(19) United States
(12) Patent Application Publication
(10) Pub. No.: US 2026/0304758 A1
(43) Pub. Date: Oct. 1, 2026

(54) SEMICONDUCTOR DEVICES INCLUDING INTERCONNECTION PATTERNS

(71) Applicant: Samsung Electronics Co., Ltd., Suwon-si (KR)

(72) Inventors: Hyojin Kim, Suwon-si (KR); Youngsoo Song, Suwon-si (KR); Gukil An, Suwon-si (KR); Rooli Choi, Suwon-si (KR)

(73) Assignee: Samsung Electronics Co., Ltd., Suwon-si (KR)

(21) Appl. No.: 19/548,467

(22) Filed: Feb. 24, 2026

(30) Foreign Application Priority Data
Mar. 31, 2025 (KR) 10-2025-0040902

(51) Int. Cl. H10B 20/25

(52) U.S. Cl. CPC H10B 20/25

(57) ABSTRACT

Embodiments of the present disclosure provide a semiconductor device comprising: a first intermetallic insulating layer comprising a first interconnection pattern extending in a first direction, a conductive via disposed adjacently to the first interconnection pattern, and a fuse portion disposed between the first interconnection pattern and the conductive via; and a second intermetallic insulating layer comprising a second interconnection pattern disposed on the first intermetallic insulating layer, contacting an upper surface of the conductive via, and extending in a second direction, intersecting the first direction, and the fuse portion is subject to an insulation breakdown when a voltage higher than a critical level is applied between the conductive via and the first interconnection pattern.

### CROSS-REFERENCE TO RELATED APPLICATIONS

This present application claims priority to and the benefit under 35 U.S.C. §119(a)-(d) of Korean Patent Application No. 10-2025-0040902, filed on Mar. 31, 2025, in the Korean Intellectual Property Office, the entire disclosure of which is incorporated herein by reference.

### FIELD

The present disclosure relates to semiconductor devices and more particularly to semiconductor devices including interconnection patterns.

### BACKGROUND

As demand for high performance, high speed, and/or multifunctionality of semiconductor devices increases, the integration of semiconductor devices is increasing. In order to overcome the limitations of the operating characteristics due to the size reduction of planar metal oxide semiconductor FET (MOSFET), efforts have been made to develop semiconductor devices comprising Multi-Bridge-Channel Field-Effect Transistors (MBCFET™) with three-dimensional channels.

Additionally, One-Time Programmable (OTP) memories have smaller bitcell sizes than eFuses and may be disposed in an array form, so that such memories have excellent space efficiency when implementing the same capacity. The OTP structure with high area competitiveness is utilized together with semiconductor devices comprising MBCFET™ with three-dimensional channels.

### SUMMARY

Some example embodiments of the present disclosure provide a semiconductor device comprising: a first intermetallic insulating layer comprising a first interconnection pattern extending in a first direction, a conductive via disposed adjacently to the first interconnection pattern, and a fuse portion disposed between the first interconnection pattern and the conductive via; and a second intermetallic insulating layer comprising a second interconnection pattern disposed on the first intermetallic insulating layer, contacting an upper surface of the conductive via, and extending in a second direction, intersecting the first direction, wherein the fuse portion is subject to an insulation breakdown when a voltage higher than a critical level is applied between the conductive via and the first interconnection pattern.

Some example embodiments of the present disclosure provide a semiconductor device comprising: a transistor structure; a first interconnection structure disposed on the transistor structure; and a second interconnection structure disposed on the first interconnection structure, wherein the first interconnection structure comprises: a first interconnection pattern extending in a first direction; and a first intermetallic insulating layer covering an upper surface of a portion of the transistor structure, an upper surface and side surfaces of the first interconnection pattern, and having a first via hole spaced apart from the first interconnection pattern, and the second interconnection structure comprises: a first conductive via filling the first via hole of the first intermetallic insulating layer; a second interconnection pattern disposed on the first intermetallic insulating layer and the first conductive via, extending in a second direction, intersecting the first interconnection pattern, and contacting an upper surface of the first conductive via; and a second intermetallic insulating layer covering an upper surface of a portion of the first interconnection structure, and side surfaces of the second interconnection pattern, and a thickness of the first intermetallic insulating layer is greater than a height of the conductive via.

Some example embodiments of the present disclosure may provide a semiconductor device comprising: a first interconnection pattern on a first level; a second interconnection pattern on a second level, higher than the first level; conductive vias respectively contacting a lower surface of the second interconnection pattern and disposed between the first level and the second level; a fuse via adjacent to the first interconnection pattern, among the conductive vias; a fuse insulating material disposed between the fuse via and the first interconnection pattern, and the fuse insulating material is subject to an insulation breakdown when a voltage higher than a critical level is applied between the fuse via and the first interconnection pattern.

Some example embodiments of the present disclosure provide a semiconductor device comprising: a first interconnection pattern on a first level; a second interconnection pattern on a second level, higher than the first level; conductive vias respectively contacting a lower surface of the second interconnection pattern and disposed between the first level and the second level; a fuse via adjacent to the first interconnection pattern, among the conductive vias; a fuse insulating material disposed between the fuse via and the first interconnection pattern, and the fuse insulating material is subject to an insulation breakdown when a voltage higher than a critical level is applied between the fuse via and the first interconnection pattern.

According to example embodiments of the present disclosure, a conductive via may be disposed on a side surface of a first interconnection pattern to implement an OTP memory, thereby increasing area competitiveness. Since the space efficiency is excellent, the size of a chip may be reduced when implementing the same capacity. The programmed OTP memory may maintain data without additional power consumption. Through this, the present disclosure may contribute to maximizing the performance and reliability of semiconductor devices while simultaneously improving space efficiency and power efficiency, and may provide the possibility of use in advanced semiconductor processes.

### BRIEF DESCRIPTION OF THE DRAWINGS

The above and other aspects, features, and advantages of the present disclosure will be more clearly understood from the following detailed description, taken in conjunction with the accompanying drawings, in which:

FIG. 1 is a schematic plan view of a semiconductor device according to some example embodiments;

FIG. 2 is a vertical cross-sectional view taken along line I-I′ of the semiconductor device illustrated in FIG. 1, and FIG. 3 is a partially enlarged view of region ‘A’ of FIG. 2;

FIG. 4 is a vertical cross-sectional view taken along line II-II′ of the semiconductor device illustrated in FIG. 1;

FIG. 5 is a conceptual operation diagram of a semiconductor device according to example embodiments of the present disclosure;

FIG. 6 is a circuit diagram of a fuse region of a semiconductor device according to example embodiments of the present disclosure;

FIG. 7A is a schematic plan view of a semiconductor device according to some example embodiments, and FIG. 7B is a vertical cross-sectional view taken along line I-I′ of the semiconductor device illustrated in FIG. 7A;

FIG. 8A is a schematic plan view of a semiconductor device according to some example embodiments, and FIG. 8B is a vertical cross-sectional view taken along line I-I′ of the semiconductor device illustrated in FIG. 8A;

FIG. 9 is a schematic plan view of a semiconductor device according to some example embodiments;

FIG. 10 is a schematic plan view of a semiconductor device according to some example embodiments;

FIG. 11 is a partially enlarged cross-sectional view illustrating an exemplary example of a semiconductor device according to some example embodiments of the present disclosure;

FIG. 12 is a partially enlarged cross-sectional view illustrating an exemplary example of a semiconductor device according to some example embodiments of the present disclosure;

FIG. 13 is a partially enlarged cross-sectional view illustrating an exemplary example of a semiconductor device according to some example embodiments of the present disclosure;

FIG. 14 is a vertical cross-sectional view taken along line I-I′ which illustrates an exemplary example of a semiconductor device according to some example embodiments of the present disclosure;

FIG. 15 is a vertical cross-sectional view taken along line I-I′ which illustrates an exemplary example of a semiconductor device according to some example embodiments of the present disclosure;

FIG. 16A, FIG. 17A and FIG. 18A are cross-sectional views taken along line I-I′ which illustrates a process sequence to explain a method of manufacturing a semiconductor device according to example embodiments; and

FIGS. 16B, 17B and 18B are cross-sectional views taken along line II-II′ which illustrates a process sequence to explain a method of manufacturing a semiconductor device according to example embodiments.

### DETAILED DESCRIPTION

Hereinafter, example embodiments of the present disclosure will be described with reference to the accompanying drawings.

Hereinafter, example embodiments of the present disclosure will be described with reference to the accompanying drawings. Unless otherwise specified, in the present specification, it may be understood that the expressions such as “on,” “above,” “upper,” “below,” “beneath,” “lower,” and “side surface,” are merely indicated based on drawings, and may actually vary depending on the direction in which the components are disposed.

In order to distinguish various elements, steps and directions from one another, ordinal numbers such as “first,” “second,” “third,” etc. may be used as labels such as specific elements, steps, and directions, terms not described using “first,” “second,” etc. in the specification may still be referred to as “first” or “second” in the claim. Additionally, terms referred to as specific ordinal numbers (e.g., “first” in certain claims) may be described as different ordinal numbers (e.g., “second” in specifications or other claims) elsewhere.

In the specification, “transistor structure” may denote a structure comprising a “transistor.”

Aspects of the present disclosure provide a semiconductor device having a programmable fuse structure.

As a solving means of the above-described aspect, some example embodiments of the present disclosure provide a semiconductor device.

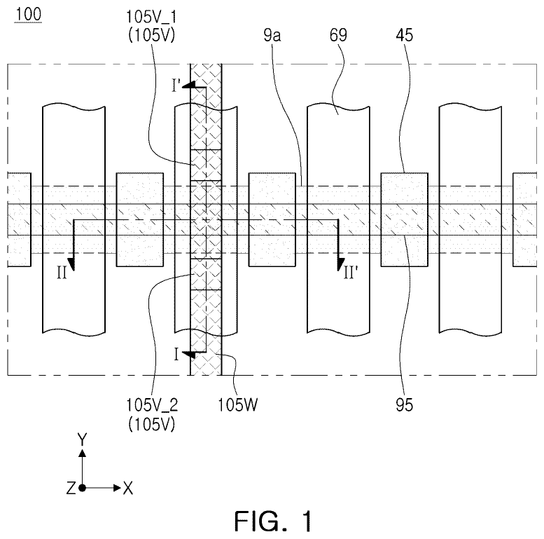

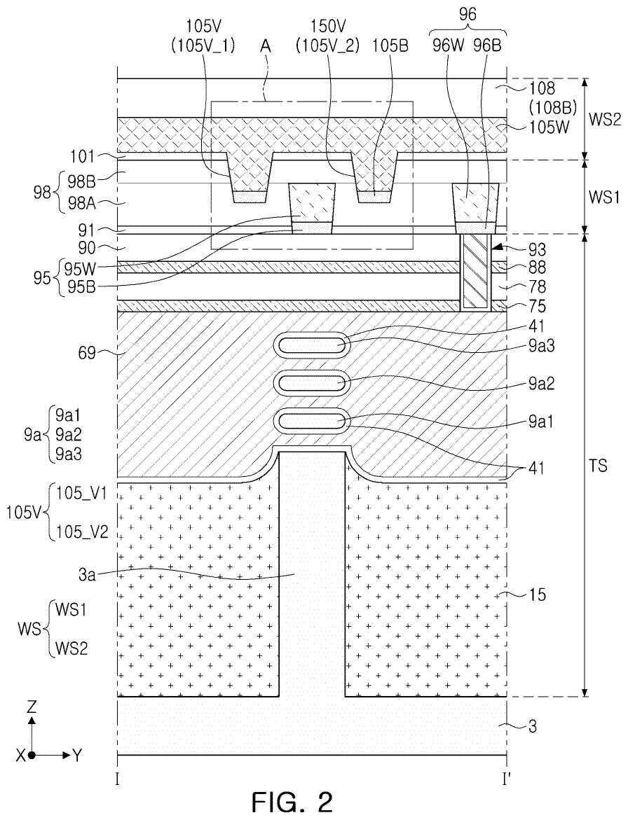

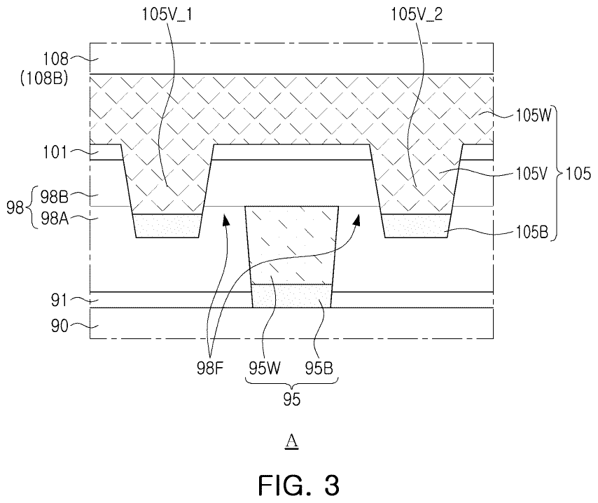

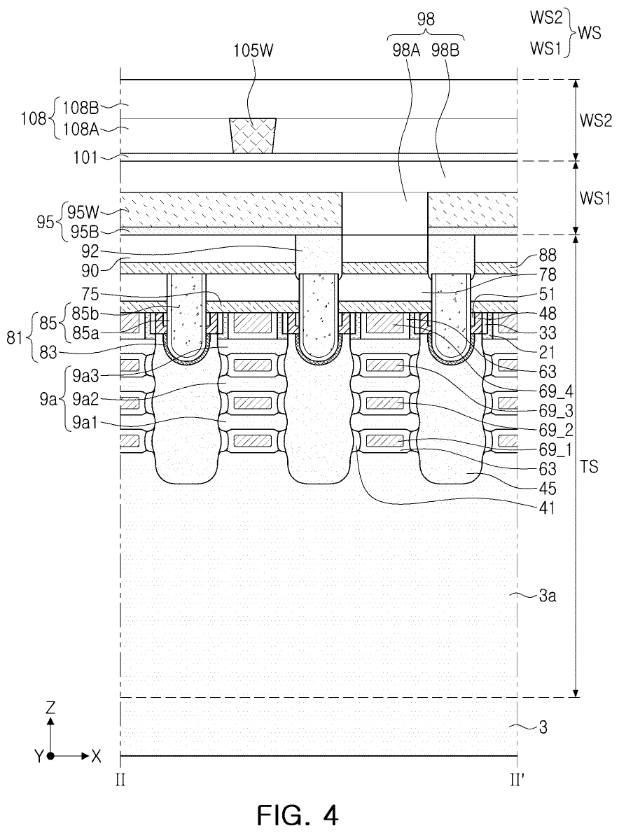

FIG. 1 is a schematic plan view of a semiconductor device according to some example embodiments. FIG. 2 is a vertical cross-sectional view taken along line I-I′ of the semiconductor device illustrated in FIG. 1, and FIG. 3 is a partially enlarged view of region ‘A’ of FIG. 2. FIG. 4 is a vertical cross-sectional view taken along line II-II′ of the semiconductor device illustrated in FIG. 1. For convenience of description, only some components of the semiconductor device are illustrated in FIG. 1.

Referring to FIGS. 1, 2, 3, and 4, a semiconductor device 100 may comprise a substrate 3, a transistor structure TS disposed on the substrate 3, and an interconnection structure WS disposed on the transistor structure TS.

The substrate 3 may be a semiconductor substrate, for example, a single crystal silicon substrate. Each of active regions 3a may have a shape protruding vertically from the substrate 3. The active region 3a may comprise a semiconductor material, for example, single crystal silicon. A device isolation region 15 may comprise an insulating material, such as silicon oxide.

The transistor structure TS may comprise source/drain regions 45, channel layers 9a, a gate electrode 69, a gate dielectric layer 63, and an insulating spacer structure 41.

The source/drain regions 45 may be spaced apart from one another in a first horizontal direction (X-direction). For example, each of the source/drain regions 45 may have an N-type conductivity type. Each of the source/drain regions 45 may comprise an epitaxially grown semiconductor material. For example, each of the source/drain regions 45 may comprise silicon.

The channel layers 9a may be disposed between the source/drain regions 45. The channel layers 9a may be disposed on the active region 3a. The channel layers 9a may be stacked and spaced apart from one another in a vertical direction (Z-direction), perpendicular to the first horizontal direction (X-direction). The channel layers 9a may be connected to the source/drain regions 45. The channel layers 9a may comprise a semiconductor material, for example, single crystal silicon.

The channel layers 9a may comprise a lower channel layer 9a1 on the first active region 3a, an intermediate channel layer 9a2 on the lower channel layer 9a1, and an upper channel layer 9a3 on the intermediate channel layer 9a2. Although the channel layers 9a are illustrated as three in FIGS. 2 and 3A, the example embodiment is not limited thereto. For example, the channel layers 9a may comprise four or more channel layers stacked and spaced apart from one another in the vertical direction (Z-direction).

The gate electrode 69 may extend in a second horizontal direction (Y-direction), perpendicular to the first horizontal direction (X-direction) and the vertical direction (Z-direction) and may surround the channel layers 9a, respectively. The gate electrode 69 may surround the channel layers 9a, respectively, and extend in the second horizontal direction (Y-direction), and may thus be disposed on the first active region 3a and the device isolation region 15.

The gate electrode 69 may comprise a lower gate portion 69_1 directly below the lower channel layer 9al, an intermediate gate portion 69_2 directly below the intermediate channel layer 9a2, an upper gate portion 69_3 directly below the upper channel layer 9a3, and an uppermost gate portion 69_4 on the upper channel layer 9a3. The lower gate portion 69_1 may be disposed between the first active region 3a and the lower channel layer 9a1, the intermediate gate portion 69_2 may be disposed between the lower channel layer 9a1 and the intermediate channel layer 9a2, and the upper gate portion 69_3 may be disposed between the intermediate channel layer 9a2 and the upper channel layer 9a3.

The gate dielectric layer 63 may be disposed between the source/drain regions 45 and the gate electrode 69 and may extend between the gate electrode 69 and the channel layers 9a. For example, the gate dielectric layer 63 may comprise a high-k dielectric. The high-k dielectric may be a dielectric having a dielectric constant higher than a dielectric constant of silicon oxide.

Then insulating spacer structure 41 may be disposed between the gate dielectric layer 63 and the source/drain regions 45. The insulating spacer structure 41 may vertically overlap the channel layers 9a.

The insulating spacer structure 41 may be disposed between the source/drain regions 45. The insulating spacer structure 41 may vertically overlap the channel layers 9a. In some example embodiments, the insulating spacer structure 41 may comprise an insulating nitride. For example, the insulating spacer structure 41 may comprise silicon nitride. Alternatively, the insulating spacer structure 41 may comprise an insulating oxide. For example, the insulating spacer structure 41 may comprise silicon oxide.

The transistor structure TS may further comprise a first insulating liner 21, a second insulating liner 33, a third insulating liner 48, and an interlayer insulating layer 51.

The interlayer insulating layer 51 may be disposed on the source/drain regions 45, the third insulating liner 48 may cover a side surface and a lower surface of the interlayer insulating layer 51, the second insulating liner 33 may be disposed between the third insulating liner 48 and the first insulating liner 21, and the first insulating liner 21 may be disposed between the second insulating liner 33 and the insulating spacer structure 41 and may be disposed between the second insulating liner 33 and the upper channel layer 9a3. The first and second insulating liners 21 and 33 may be disposed on the upper channel layer 9a3, and the third insulating liner 33 may be disposed on the source/drain regions 45.

The upper surfaces of the gate electrode 69, the gate dielectric layer 63, the insulating spacer structure 41, the first insulating liner 21, the second insulating liner 33, the third insulating liner 48 and the interlayer insulating layer 51 may form a coplanar surface.

The transistor structure TS may further comprise a first capping insulating layer 75, a first interlayer insulating layer 78, a second capping insulating layer 88, and a second interlayer insulating layer 90 which are sequentially stacked.

The first capping insulating layer 75 may cover the gate electrode 69, the gate dielectric layer 63, the insulating spacer structure 41, the first insulating liner 21, the second insulating liner 33, the third insulating liner 48 and the interlayer insulating layer 51.

The first and second interlayer insulating layers 78 and 90 may comprise, for example, at least one of a low-k dielectric, an oxide, a nitride, and an oxynitride, and may comprise silicon oxide, silicon oxynitride, SiOC, SiCOH, or combinations thereof.

The first and second interlayer insulating layers 78 and 90 may comprise a low-K dielectric. According to some example embodiments, the first and second interlayer insulating layers 78 and 90 may comprise a material in which at least one of a fluorine (F), a carbon (C), or a methyl group (CH₃) is bonded to silicon oxide. However, a material forming the first and second interlayer insulating layers 78 and 90 is not limited thereto.

The first and second capping insulating layers 75 and 88 may comprise a different material from the first and second interlayer insulating layers 78 and 90 and the interlayer insulating layer 51. For example, the first and second capping insulating layers 75 and 88 may comprise silicon nitride or metal oxide, and the first and second interlayer insulating layers 78 and 90 and the interlayer insulating layer 51 may comprise silicon oxide or a low-k dielectric having a dielectric constant lower than that of silicon oxide.

A thickness of each of the first and second interlayer insulating layers 78 and 90 may be greater than a thickness of each of the first and second capping insulating layers 75 and 88.

The transistor structure TS may further comprise a source/drain contact structure 81 and a gate contact structure 93.

The source/drain contact structure 81 may be in contact with and electrically connected to the source/drain region 45. For example, the source/drain contact structure 81 may comprise a metal-semiconductor compound layer 83, a first source/drain contact plug 85 on the metal-semiconductor compound layer 83, and a second source/drain contact plug 92.

The first source/drain contact plug 85 may comprise a plug conductive pattern 85b and a barrier layer 85a covering a side surface and a lower surface of the plug conductive pattern 85b. In each of the source/drain contact structures 81, the metal-semiconductor compound layer 83 may be in contact with the source/drain region 45. In the source/drain contact structure 81, the metal-semiconductor compound layer 83 may be disposed between the source/drain region 45 and the source/drain contact plug 85. The second capping insulating layer 88 may be disposed on upper surfaces of the source/drain contact structure 81 and upper surface of the first interlayer insulating layer 78.

The second source/drain contact plug 92 may penetrate through the second interlayer insulating layer 90 and the second capping insulating layer 88 and may be electrically connected to the first source/drain contact plug 85. The second source/drain contact plug 92 may be electrically connected to the first source/drain contact plug 85.

In some of the source/drain regions 45, the second source/drain contact plug 92 may not be disposed on the first source/drain contact plug 85. This may be referred to as a dummy source/drain region. The second capping insulating layer 88 and the second interlayer insulating layer 90 may be disposed on the first source/drain contact plug 85. The first source/drain contact plug 85 on the dummy source/drain region may be spaced apart from a first interconnection pattern 95.

The gate contact structure 93 may penetrate through the second interlayer insulating layer 90, the second capping insulating layer 88, the first interlayer insulating layer 78 and the first capping insulating layer 75 and may be electrically connected to the gate electrode 69. The gate contact structure 93 may be electrically connected to the gate electrode 69.

The interconnection structure WS may comprise a first interconnection structure WS1 and a second interconnection structure WS2 on the first interconnection structure WS1.

The first interconnection structure WS1 may comprise a first interconnection pattern 95, a gate interconnection pattern 96, a first intermetallic insulating layer 98 and a first etch stop layer 91.

The first interconnection pattern 95 may be disposed on the second interlayer insulating layer 90. The first interconnection pattern 95 may be disposed on the second source/drain contact plug 92 so that the first interconnection pattern 95 may extend in the first horizontal direction (X-direction) and be electrically connected to the second source/drain contact plug 92. The first interconnection pattern 95 may be electrically connected to one source/drain region 45 to which the second source/drain contact plug 92, among the source/drain regions 45, is connected through the second source/drain contact plug 92. The first interconnection pattern 95 may have a first level in the vertical direction (Z-direction).

The first interconnection pattern 95 may be electrically connected to the second source/drain contact plug 92. The first interconnection pattern 95 may be disposed on the second interlayer insulating layer 90 and the second source/drain contact plug 92. The first interconnection pattern 95 may be connected to the second source/drain contact plug 92. The first interconnection pattern 95 may have a shape in which a width thereof gradually increases in a direction oriented toward a second intermetallic insulating layer 108 within the first intermetallic insulating layer 98. A width of an upper surface of the first interconnection pattern 95 may be larger than a width of a lower surface of the first interconnection pattern 95.

The first interconnection pattern 95 may comprise a first conductive interconnection line 95W and a first barrier layer 95B disposed on a lower surface of the first conductive interconnection line 95W. A thickness of the first barrier layer 95B in the vertical direction (Z-direction) may be thicker than a thickness of the first etch stop layer 91. The first barrier layer 95B may be disposed between the lower surface of the first conductive interconnection line 95W and an upper surface of the second interlayer insulating layer 90. A first barrier layer 96B may be disposed on the lower surface of the first conductive interconnection line 95W so that a first metal layer 95M may be filled within the first conductive interconnection line 95W.

The first conductive interconnection line 95W may be comprised of the first metal layer 95M. The first metal layer 95M may be formed of copper (Cu), tungsten (W), aluminum (Al), cobalt (Co), ruthenium (Ru), or combinations thereof. Additionally, the first barrier layer 95B may be formed of tantalum (Ta), tantalum nitride (TaN), titanium (Ti), titanium nitride (TiN), or combinations thereof.

The gate interconnection pattern 96 may be electrically connected to the gate contact structure 93. The gate interconnection pattern 96 may be arranged on the second interlayer insulating layer 90 and the gate contact structure 93. The gate interconnection pattern 96 may be connected to the gate contact structure 93.

The gate interconnection pattern 96 may comprise a gate interconnection 96W and a gate barrier layer 96B disposed on a lower surface of the gate interconnection 96W. The gate barrier layer 96B may be disposed between the lower surface of the gate interconnection 96W and the upper surface of the second interlayer insulating layer 90. The gate barrier layer 96B may be disposed on the lower surface of the gate interconnection 96W so that a gate metal layer 96M may be filled within the gate interconnection 96W. A thickness of the gate barrier layer 96B in the vertical direction (Z-direction) may be thicker than a thickness of the first etching stop layer 91.

The gate metal layer 96M may be formed of copper (Cu), tungsten (W), aluminum (Al), cobalt (Co), ruthenium (Ru), or combinations thereof. Additionally, the gate barrier layer 96B may be formed of tantalum (Ta), tantalum nitride (TaN), titanium (Ti), titanium nitride (TiN), or combinations thereof.

The first intermetallic insulating layer 98 may be disposed on the second interlayer insulating layer 90, the gate interconnection pattern 96 and the first interconnection pattern 95. The first intermetallic insulating layer 98 may be disposed on the second interlayer insulating layer 90 and the first interconnection pattern 95. The first intermetallic insulating layer 98 may be disposed on the second interlayer insulating layer 90 and the gate interconnection pattern 96. The first intermetallic insulating layer 98 may cover an upper surface of a portion of the transistor structure TS, an upper surface and side surfaces of the first interconnection pattern 95, and may have via holes spaced apart from the first interconnection pattern 95 on an upper surface thereof.

The first intermetallic insulating layer 98 may be comprised of a lower first intermetallic insulating layer 98A and an upper first intermetallic insulating layer 98B disposed thereon. The lower first intermetallic insulating layer 98A may be disposed to cover an upper portion of a portion of the transistor structure TS and side surfaces of the first interconnection pattern 95. The upper first intermetallic insulating layer 98B may be disposed to cover the upper surface of the first interconnection pattern 95 and the lower first intermetallic insulating layer 98A. The lower first intermetallic insulating layer 98A and the upper first intermetallic insulating layer 98B may be formed of the same material, and boundaries thereof may be difficult to identify with the naked eye. Via holes and conductive vias 105V filling the via holes may be disposed to penetrate through the upper first intermetallic insulating layer 98B and to penetrate through a portion of the lower first intermetallic insulating layer 98A.

A thickness of the first intermetallic insulating layer 98 in the vertical direction (Z-direction) may be greater than a height of the conductive vias 105V in the vertical direction (Z-direction). A lower surface of the conductive vias 105V may be in contact with an upper surface of the via holes disposed on a portion of an upper surface of the first intermetallic insulating layer 98.

The first intermetallic insulating layer 98 may comprise a fuse portion 98F disposed between the first interconnection pattern 98 and the conductive via 105V. The fuse portion 98F may denote a portion of the first intermetallic insulating layer 98 disposed between a first conductive via 105V_1 and the first interconnection pattern 98. The fuse portion 98F may denote a portion of the first intermetallic insulating layer 98 disposed between a second conductive via 105V_2 and the first interconnection pattern 98. Boundaries between the first intermetallic insulating layer 98 and the fuse portion 98F may be unclear. The fuse portion 98F may denote a region in which an insulation breakdown occurs, in the first intermetallic insulating layer 98. A material forming the first intermetallic insulating layer 98 disposed on the fuse portion 98F may be referred to as a fuse insulating material. The fuse insulating material may comprise an oxide.

The first intermetallic insulating layer 98 may have via holes disposed on the first intermetallic insulating layer 98. The first intermetallic insulating layer 98 may have a first via hole covering an upper surface of a portion of the second interlayer insulating layer 90 and an upper surface and side surfaces of the first interconnection pattern 95, and spaced apart from the first interconnection pattern 95. The first intermetallic insulating layer 98 may have a second via hole covering an upper surface of a portion of the second interlayer insulating layer 90 and an upper surface and side surfaces of the first interconnection pattern 95, and spaced apart from the first interconnection pattern 95. The first and second conductive vias 105V_1 and 105V_2 may be disposed to fill the first and second via holes, respectively. Upper surfaces of the first and second conductive vias 105V_1 and 105V_2 may be in contact with a lower surface of the second interconnection pattern. Heights of the first and second conductive vias 105V_1 and 105V_2 may be substantially the same. The first and second conductive vias 105V_1 and 105V_2 may be formed simultaneously. A distance between the first conductive via 105V_1 and the first interconnection pattern 95 may be substantially the same as a distance between the second conductive via 105V_2 and the first interconnection pattern 95. An insulation breakdown of the first interconnection pattern 95 and the first conductive via 105V_1 and an insulation breakdown of the first interconnection pattern 95 and the second conductive via 105V_2 may occur substantially simultaneously.

In some example embodiments, the first intermetallic insulating layer 98 may comprise an insulating material. The first intermetallic insulating layer 98 may comprise, for example, at least one of a low-k dielectric, an oxide, a nitride and an oxynitride, and may comprise silicon oxide, silicon oxynitride, SiOC, SiCOH, or combinations thereof.

The first intermetallic insulating layer 98 may comprise a low-k dielectric. According to some example embodiments, the first intermetallic insulating layer 98 may comprise a material in which at least one of fluorine (F), carbon (C), or methyl group (CH₃) is bonded to silicon oxide. According to some example embodiments, the first intermetallic insulating layer 98 may comprise porous silicon oxide having pores. However, the material forming the first intermetallic insulating layer 98 is not limited thereto.

The first etch stop layer 91 may be disposed between an upper portion of a portion of the second interlayer insulating layer 90 and the first intermetallic insulating layer 98. The first etch stop layer 91 may be disposed to conformally cover an upper surface of a portion of the second interlayer insulating layer 90 on which the first interconnection pattern 95 is not disposed. In some example embodiments, when viewed from the side cross-section, the first etch stop layer 91 may be configured in plural so that a plurality of first etch stop layer 91 are spaced apart from one another with the first interconnection pattern 95 interposed therebetween, and a portion of a side surface of the first interconnection pattern 95 may be disposed to respectively contact side surfaces of the first etch stop layers 91 adjacent to one another. The first etch stop layer 91 may be disposed between a second interconnection pattern 105 and the first intermetallic insulating layer 98. Specifically, not only the first intermetallic insulating layer 98 but also the first etching stop layer 91 may be disposed between the second interconnection pattern 105 and the first interconnection pattern 95. The first intermetallic insulating layer 98 may be disposed on the first interconnection pattern 95. The first etching stop layer 91 may be disposed on the first intermetallic insulating layer 98. The second interconnection pattern 105 may be disposed on the first etching stop layer 91.

The first etching stop layer 91 may be formed of a material having a different etching selectivity from the first intermetallic insulating layer 98. The first etching stop layer 91 may be an insulating layer comprising an insulating material such as silicon oxide, silicon nitride, or silicon oxynitride. According to some example embodiments, the etching stop layer may be a conductive layer comprising a conductive material such as a metal, a metal nitride, or a metal silicide nitride film. According to some example embodiments, the first etch stop layer 91 may be formed to comprise a material such as polysilicon. However, the material forming the first etch stop layer 91 is not limited thereto.

The second interconnection structure WS2 may comprise a second interconnection pattern 105, conductive vias 105V, a second intermetallic insulating layer 108, and a second etch stop layer 101.

The second interconnection pattern 105 may be disposed on the first intermetallic insulating layer 98. The second interconnection pattern 105 may be disposed to extend in the second horizontal direction (Y-direction). The second interconnection pattern 105 may be disposed on the first intermetallic insulating layer 98 and the first and second conductive vias 105V_1 and 105V_2. The second interconnection pattern 105 may be disposed on a second level, higher than the first level on which the first interconnection pattern 95 is disposed.

The second interconnection pattern 105 may be comprised of a second conductive interconnection line 105W and a conductive via 105V. The second conductive interconnection line 105W may be an interconnection line 105 extending in the second horizontal direction (Y-direction), orthogonal to the first interconnection pattern 95, and the conductive via 105V may be a via in which a metal material is filled and disposed inside via holes disposed on the first intermetallic insulating layer 98. For convenience of explanation, only conductive vias 105V_1 and 105V_2 adjacent to the first interconnection pattern 95, among the conductive vias 105V, are illustrated in the drawing. The first interconnection pattern 95 may be comprised in the first layer metal interconnection line (e.g., a M1 layer of the semiconductor), the second conductive interconnection line 105W may be comprised in the second layer metal interconnection (e.g., a M2 layer of the semiconductor), and the conductive via 105V may correspond to a via disposed between the first layer metal interconnection line and the second layer metal interconnection line.

The second interconnection pattern 105 may comprise a second metal layer 105M filling the second conductive interconnection line 105W and the conductive via 105V, and a second barrier layer 105B disposed on a lower surface of the conductive via 105V filled with the second metal layer 105M. The second barrier layer 105B may be disposed between the lower surface of the conductive via 105V and an upper surface of the first intermetallic insulating layer 98. The second barrier layer 105B may be disposed on the lower surface of the conductive via 105V so that the second metal layer 105M filling the conductive via 105V may be filled within the via. A thickness of the second barrier layer 105B in the vertical direction (Z-direction) may be thicker than a thickness of the second etch stop layer 101.

The second metal layer 105M may be formed of copper (Cu), tungsten (W), aluminum (Al), cobalt (Co), ruthenium (Ru), or combinations thereof. Additionally, the second barrier layer 105B may be formed of tantalum (Ta), tantalum nitride (TaN), titanium (Ti), titanium nitride (TiN), or combinations thereof.

The conductive vias 105V may be disposed adjacently to the first interconnection pattern 95. The conductive vias 105V may comprise a first conductive via 105V_1 and a second conductive via 105V_2. The first and second conductive vias 105V_1 and 105V_2 may fill the first and second via holes of the first intermetallic insulating layer 98, respectively. The conductive via 105V disposed adjacently to the first interconnection pattern 95 may be referred to as a via for a fuse.

An upper surface of the conductive vias 105V may be in contact with the second interconnection pattern 105. The upper surface of the conductive vias 105V may be in contact with a lower surface of the second interconnection pattern 105. The conductive vias 105V may be disposed on the first intermetallic insulating layer 98. The conductive vias 105V may be disposed in the via holes of the first intermetallic insulating layer 98. Each of the conductive vias 105V may be in contact with the lower surface of the second interconnection pattern 105 and may be disposed between the first level of the first interconnection pattern 95 and the second level of the second interconnection pattern 105.

The conductive vias 105V may have a shape in which a width thereof gradually increases in a direction oriented toward the second intermetallic insulating layer 108 within the first intermetallic insulating layer 98. A width of an upper surface of the conductive via 105V may be greater than a width of the lower surface of the conductive via 105V.

A level of the lower surface of the conductive via 105V may be equal to or lower than a level of the upper surface of the first interconnection pattern 95. A level of the lower surface of the first conductive via 105V_1 may be equal to or lower than a level of the upper surface of the first interconnection pattern 95. A level of the lower surface of the second conductive via 105V_2 may be equal to or lower than the level of the upper surface of the first interconnection pattern 95. The conductive vias 105V may overlap the first interconnection pattern 95 in the second horizontal direction (Y-direction). The second interconnection pattern 105 may extend in the second horizontal direction (Y-direction), the conductive vias 105V may be disposed in the second interconnection pattern 105, and the conductive vias 105V may overlap the first interconnection pattern 95 in the second horizontal direction (Y-direction).

When the first interconnection pattern 95 and the conductive vias 105V partially overlap one another in the second horizontal direction (Y-direction), a current path may be optimized. For example, a length of an insulation breakdown path between the conductive vias 105V and the first interconnection pattern 95 may be maintained within a certain range. In some example embodiments, in one of the conductive vias 105V, a distance between the conductive via 105V and the first interconnection pattern 95 in the second horizontal direction (Y-direction) may be about 5 nm to about 12 nm, specifically about 7 nm to about 10 nm. A thickness of the first interconnection pattern 95 may be about 13 nm to about 26 nm, specifically about 15 nm to about 23 nm. In the example embodiment, a range of voltage required for insulation breakdown may be reliably predicted through each numerical range. The current transfer efficiency between the conductive vias 105V and the first interconnection pattern 95 after insulation breakdown may be improved. Predictability may be secured in the case of insulation breakdown, and the reliability of the semiconductor device 100 may be increased. The electrical connection formed after insulation breakdown may be maintained more stably, and long-term reliability may be improved.

The second intermetallic insulating layer 108 may be disposed on the first intermetallic insulating layer 98 and the second interconnection pattern 105. The second intermetallic insulating layer 108 may cover an upper portion of a portion of the first interconnection structure WS1 and side surfaces of the second interconnection pattern 105. In some example embodiments, the second intermetallic insulating layer 108 may cover an upper surface of the second interconnection pattern 105.

The second intermetallic insulating layer 108 may be comprised of a lower second intermetallic insulating layer 108A and an upper second intermetallic insulating layer 108B disposed thereon. The lower second intermetallic insulating layer 108A may be disposed to cover an upper surface of a portion of the first interconnection structure WS1 and side surfaces of the second interconnection pattern 105. The upper second intermetallic insulating layer 108B may be disposed to cover the upper surface of the second interconnection pattern 105 and the lower second intermetallic insulating layer 108A. The lower second intermetallic insulating layer 108A and the upper second intermetallic insulating layer 108B may be formed of the same material, and boundaries thereof may be difficult to identify with the naked eye.

In some example embodiments, the second intermetallic insulating layer 108 may comprise an insulating material. The second intermetallic insulating layer 108 may comprise, for example, at least one of a low-k dielectric, an oxide, a nitride, and an oxynitride, and may comprise silicon oxide, silicon oxynitride, SiOC, SiCOH, or combinations thereof.

The second intermetallic insulating layer 108 may comprise a low-k dielectric. In some example embodiments, the first intermetallic insulating layer 98 may comprise a material in which at least one of a fluorine (F), a carbon (C), or a methyl group (CH₃) is bonded to silicon oxide. In some example embodiments, the first intermetallic insulating layer 98 may comprise porous silicon oxide having pores. However, the material forming the first intermetallic insulating layer 98 is not limited thereto.

The second etch stop layer 101 may be disposed between an upper surface of a portion of the first intermetallic insulating layer 98 and the second intermetallic insulating layer 108. The second etch stop layer 101 may be disposed to conformally cover an upper surface of a portion of the first intermetallic insulating layer 98 on which the conductive vias 105V are not disposed. In some example embodiments, when viewed from the side cross-section, the second etch stop layer 101 may be configured in plural so that a plurality of second etch stop layer 101 are spaced apart from one another with upper surfaces of the conductive vias 105V interposed therebetween, and a portion of side surfaces of the conductive vias 105V may be disposed to respectively contact side surfaces of the second etch stop layers 101 adjacent to one another.

The second etch stop layer 101 may be formed of a material having a different etch selectivity from the second intermetallic insulating layer 108. The second etch stop layer 101 may be an insulating layer comprising an insulating material such as silicon oxide, silicon nitride, or silicon oxynitride. According to some example embodiments, the second etch stop layer 101 may be a conductive layer comprising a conductive material such as a metal, a metal nitride, or a metal silicide nitride film. According to some example embodiments, the second etch stop layer 101 may be formed to comprise a material such as polysilicon. However, the material forming the second etch stop layer 101 is not limited thereto.

The first and second intermetallic insulating layers 98 and 108 may be provided as a region for forming an interconnection line such as a BEOL, and some of the interconnection lines disposed on the first and second intermetallic insulating layers 98 and 108 may be electrically connected to the transistor structure TS through the second source/drain contact plug 92 and the gate contact structure 93 disposed within the second interlayer insulating layer 90. Additionally, multiple interconnection layers may be further arranged on the second intermetallic insulating layer 108.

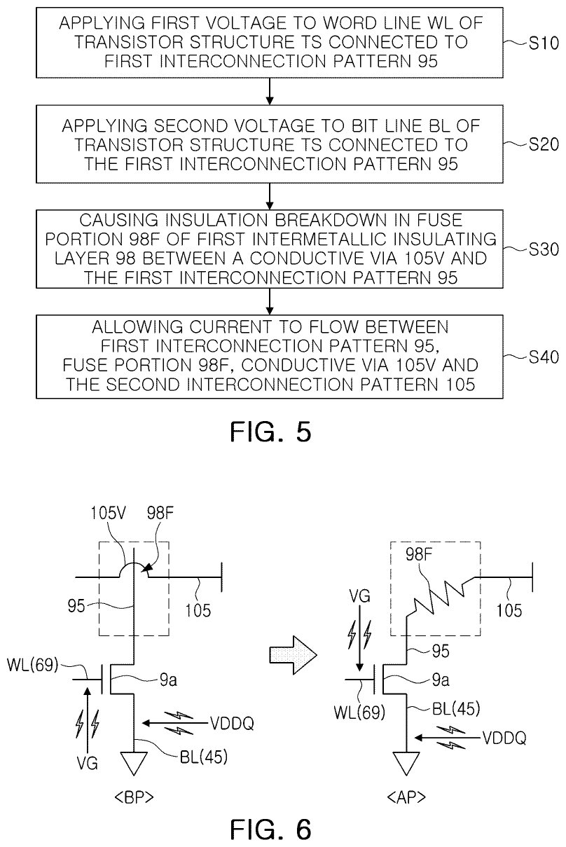

FIG. 5 is a conceptual operation diagram of a semiconductor device according to example embodiments of the present disclosure. FIG. 5 is a flow diagram illustrating general operations accompanying the present disclosure for programming a semiconductor device 100 comprising a fuse structure. FIG. 6 is a circuit diagram of a fuse region of a semiconductor device according to example embodiments of the present disclosure reflecting changes according to the operation of FIG. 5.

Referring to FIG. 5, programming a semiconductor device according to this example embodiment may comprise: applying a first voltage to a word line WL of a transistor structure TS connected to a first interconnection pattern 95 (S10), applying a second voltage to a bit line BL of a transistor structure TS connected to the first interconnection pattern 95 (S20), causing an insulation breakdown in a fuse portion 98F of a first intermetallic insulating layer 98 between a conductive via 105V and the first interconnection pattern 95 (S30), and allowing current to flow between the first interconnection pattern 95, the fuse portion 98F, the conductive via 105V and the second interconnection pattern 105 (S40).

A first voltage may be applied to a word line of a transistor connected to the first interconnection pattern 95 (S10). The first voltage may be applied to the word line WL of the transistor structure TS. The word line WL may perform a function of selectively activating or deactivating a memory cell corresponding to a specific address through a gate electrode 69 of the transistor structure TS. Depending on the voltage applied to the word line, the transistor performs a switching operation, so that data may be read or stored through a bit line BL.

For example, the word line WL may be comprised of a gate interconnection pattern 96, a gate contact structure 93, and a gate electrode 69. When the first voltage is applied to the gate electrode 69, a channel may be formed through which current may flow between the source/drain regions 45 through the channel layers 9a surrounding the gate electrode 69.

When the first voltage is applied to the word line WL of the transistor structure TS, the second voltage may be applied to the bit line of the transistor structure connected to the first interconnection pattern 95 (S20). For example, the second voltage may comprise, for example, a data input/output voltage VDDQ. The data input/output voltage VDDQ refers to a voltage level operating in a data input/output (Data I/O) interface within a memory device, and may serve to ensure stable signal transmission in a data path connected to the bit line BL.

When the second voltage is applied to the bit line BL, current may flow between the source/drain regions 45 through the channel formed by the first voltage applied to the word line WL.

When the second voltage is applied to the bit line BL of the transistor structure TS connected to the first interconnection pattern 95, an insulation breakdown may occur in the fuse portion 98F of the first intermetallic insulating layer 98 between the conductive via 105V and the first interconnection pattern 95 (S30). When current flows in the source/drain regions 45, a voltage substantially equal to the second voltage may be applied to the first interconnection pattern 95 connected to the source/drain regions 45. When the second voltage is applied to the first interconnection pattern 95, the fuse portion 98F of the first intermetallic insulating layer 98 disposed between the conductive via 105V of the second interconnection pattern 105 and the first interconnection pattern 95 may be damaged. For example, an insulation breakdown of oxides disposed in the fuse portion 98F may occur.

When the insulation breakdown occurs in the fuse portion 98F, current may flow between the first interconnection pattern 95, the fuse portion 98F, the conductive via 105V, and the second interconnection pattern 105 (S40). A voltage or an electric field may be applied between the first interconnection pattern 95 and the conductive via 105V by the second voltage, and the insulation properties of the insulating material arranged in the fuse portion 98F may be lost, and current may flow.

Referring to FIG. 6, a circuit diagram BP may be a circuit diagram illustrating before an insulation breakdown occurs in the fuse portion 98F through programming. A circuit diagram AP may be a circuit diagram illustrating after an insulation breakdown occurs in the fuse portion 98F through programming.

Referring to FIG. 5 and the circuit diagram BP, the first voltage may be applied to the word line WL, and the second voltage may be applied to the bit line BL. When the second voltage is applied to the bit line BL, the insulation breakdown may occur in the fuse portion 98F disposed between the second interconnection pattern 105 and the first interconnection pattern 95 forming a portion of the bit line BL. Referring to FIG. 4, when a voltage (e.g., the second voltage) higher than a critical level is applied between the fuse via 105V and the first interconnection pattern 95, the fuse portion 98F may be subject to an insulation breakdown. Referring to FIG. 4, when the fuse portion 98F is subject to the insulation breakdown, current may flow between the first interconnection pattern 95 and the second interconnection pattern 105 through the fuse portion 98F, and after a voltage (e.g., the second voltage) higher than the critical level is applied between the fuse vias 105V and the first interconnection pattern 95, the first interconnection pattern 95, the fuse portion 98F, the fuse via 105V and the second interconnection pattern 105 may be electrically connected to one another. Referring to FIG. 4, the first interconnection pattern 95, the fuse insulating material 98F after the insulation breakdown, the conductive via 105V, and the second interconnection pattern 105 may be electrically connected to one another.

Referring to FIG. 5 and the circuit diagram AP, the first voltage may be applied to the word line WL, and the second voltage may be applied to the bit line BL. Applying the first voltage to the word line WL may comprise a portion of operating the transistor structure TS. When the second voltage is applied to the bit line BL, current may flow between the second interconnection pattern 105 and the first interconnection pattern 95 through the fuse portion 98F subjected to the insulation breakdown.

Referring to the circuit diagrams BP and AP, when the semiconductor device operates, if the fuse portion 98F is not damaged, the semiconductor device may read “0”. If the fuse portion 98F is damaged, The semiconductor device may read “1”. If the fuse portion 98F is damaged, the fuse portion 98F between the first interconnection pattern 95 and the second interconnection pattern 105 may act as a resistor.

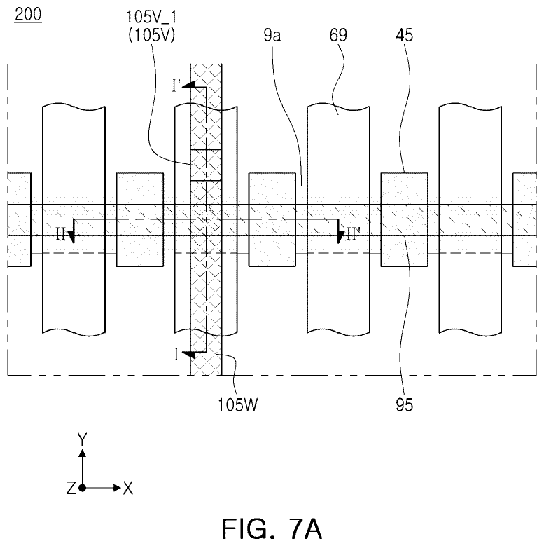

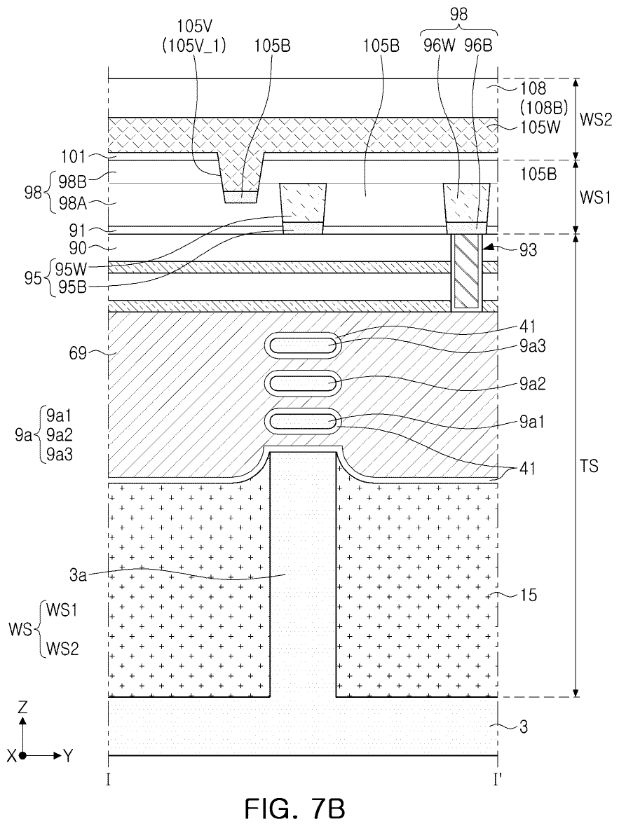

FIG. 7A is a schematic plan view of a semiconductor device according to some example embodiments, and FIG. 7B is a vertical cross-sectional view taken along line I-I′ of the semiconductor device illustrated in FIG. 7A.

Referring to FIGS. 7A and 7B, a semiconductor device 200 may be understood to have a structure similar to that of the semiconductor device 100 illustrated in FIGS. 1 to 6, except that there is one conductive via 105V adjacent to the first interconnection pattern 95. Accordingly, the description of the semiconductor device 100 illustrated in FIGS. 1 to 6 may be combined with the description of the semiconductor device 200 according to this example embodiment, unless there is a specifically contrary description.

The second interconnection pattern 105 may be comprised of a second conductive interconnection line 105W and a conductive via 105V_1. The second conductive interconnection line 105W may be an interconnection line 105 extending in the second horizontal direction (Y-direction), orthogonal to the first interconnection pattern 95, and the conductive via 105V_1 may be a via in which a metal material is filled and disposed inside via holes disposed on the first intermetallic insulating layer 98. Only one conductive via 105V_1 adjacent to the first interconnection pattern 95 may be disposed. An insulation breakdown may occur for a portion of the first intermetallic insulating layer 98 disposed between the conductive via 105V_1 and the first interconnection pattern 95.

When the insulation breakdown occurs between the conductive via 105V_1 and the first interconnection pattern 95, current may flow through the conductive via 105V_1. In some example embodiments, a single conductive via 105V_1 may sufficiently perform the desired function. For example, the insulation breakdown may be induced by a local electric field concentration of the fuse portion 98F of the first intermetallic insulating layer 98, and in this process, a resistance value between the first interconnection pattern 95 and the conductive via 105V_1 may change rapidly. The insulation breakdown may be used to program an OTP memory. After an insulation layer of the fuse portion 98F is damaged, the conductive via 105V_1 and the first interconnection pattern 95 may be directly connected to lower the resistance, and the corresponding state may be maintained. The insulation breakdown may be designed to ensure sufficient current flow with a single via, thereby simplifying the process and improving area efficiency. The insulation breakdown may contribute to increasing the integration density of the OTP memory device.

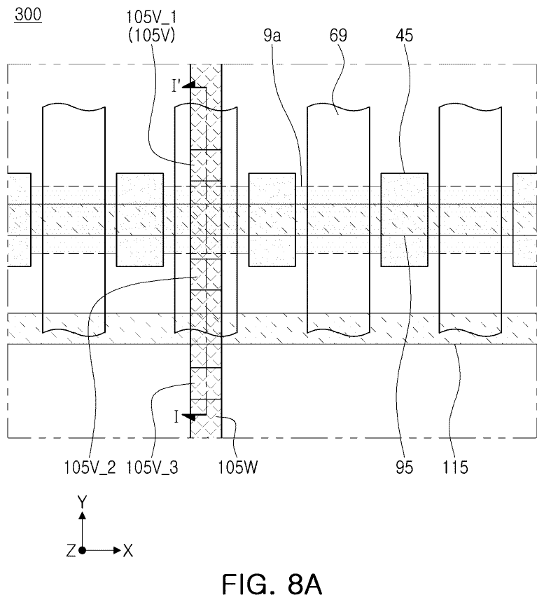

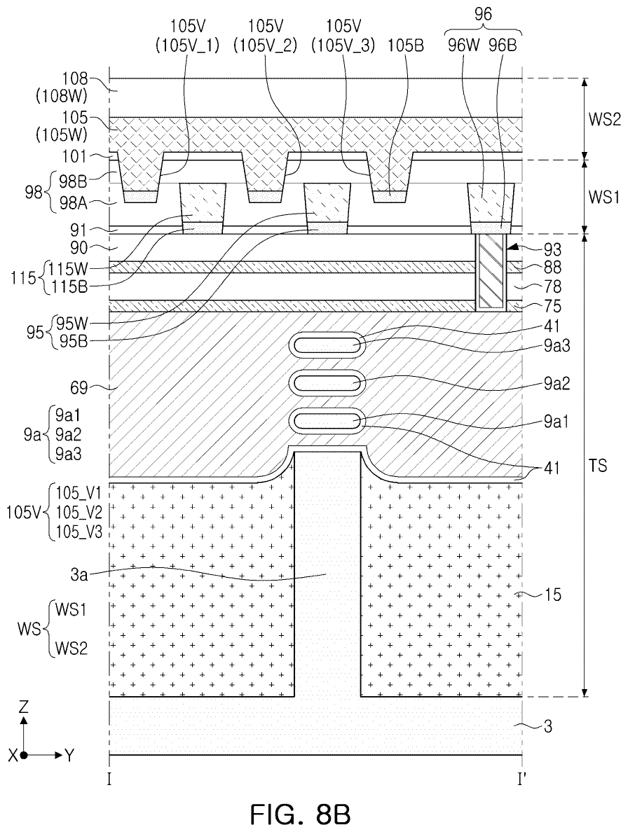

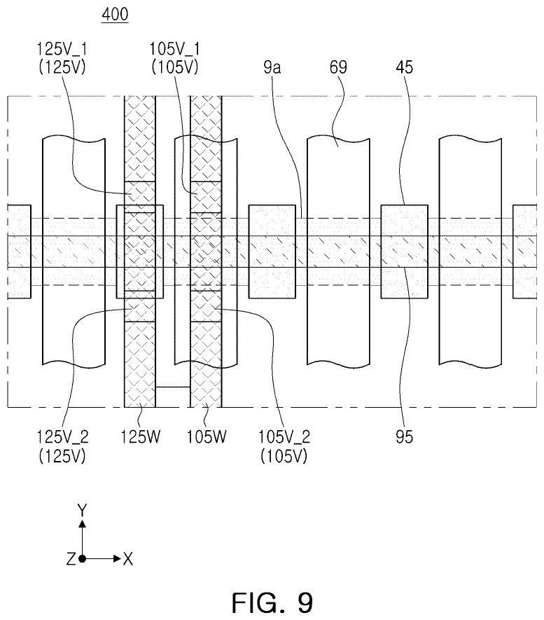

FIG. 8A is a schematic plan view of a semiconductor device according to some example embodiments, and FIG. 8B is a vertical cross-sectional view taken along line I-I′ of the semiconductor device illustrated in FIG. 9A.

Referring to FIGS. 8A and 8B, a semiconductor device 300 may be understood as having a structure similar to that of the semiconductor device 100 illustrated in FIGS. 1 to 6, except that the semiconductor device 300 further comprises a third interconnection pattern 115 extending substantially parallel to the first interconnection pattern 95 and a third conductive via 105V_3 disposed on an opposite side of the second conductive via 105V_2 with respect to the third interconnection pattern 115. Accordingly, the description of the semiconductor device 100 illustrated in FIGS. 1 to 6 may be combined with the description of the semiconductor device 300 according to this example embodiment, unless there is a specifically contrary description.

The semiconductor device 300 may further comprise a third interconnection pattern 115 extending substantially parallel to the first interconnection pattern 95 and a third conductive via 105V_3 disposed on an opposite side of the second conductive via 105V_2 with respect to the third interconnection pattern 115.

The third interconnection pattern 115 may be comprised of a third conductive interconnection line 115W and a conductive via 115V. The third interconnection pattern 115 may extend parallel to the first interconnection pattern in the second horizontal direction (Y-direction). The first intermetallic insulating layer 98 may comprise a third via hole disposed on an opposite side of the second via hole with respect to the third interconnection pattern 115. A second conductive via 105V_2 may be disposed in the second via hole. A third conductive via 105V_3 may be disposed in the third via hole. The second conductive via 105V_2 may be disposed between the first interconnection pattern 95 and the third interconnection pattern 115. An upper surface of the third conductive via 105V_3 may be in contact with the lower surface of the second interconnection pattern 105.

When three vias are provided, the number of fuse portions 98F in which the insulation breakdown occurs may increase. The probability that the fuse portions 98F between the conductive via 105V and the first interconnection pattern 95 may be damaged increases, and the OTP function may be performed more stably. For example, in multi-via structures 105V_1, 105V_2 and 105V_3, even if insulation breakdown occurs incompletely in a single conductive via, additional insulation breakdown may occur among other vias. This may increase a success rate in a programming process, and may ensure lower resistance. This may improve the reliability of the OTP-ROM structure, and the current may flow more smoothly. Additionally, by utilizing the multi-via structure, the damage to the fuse portion 98F may occur simultaneously at multiple points rather than locally. This may allow the collapse of the fuse portion 98F to occur more uniformly, and the electrical characteristics may be maintained more stably. This design may contribute to improving the performance and lifespan of the semiconductor device.

Additionally, when the first interconnection pattern 95 disposed on the existing first interconnection structure WS1 is maintained unchangeably and the third interconnection pattern 115 is added at the same time, the second and third conductive vias 105V_2 and 105V_3 may be additionally comprised, so that an electrical connection with the third interconnection pattern 115 may occur. In addition to the first interconnection pattern 95, when the third interconnection pattern 115 is utilized, the current may be distributed, and local heat generation due to the current concentrated on the first interconnection pattern 95 may be reduced.

FIG. 9 is a schematic plan view of a semiconductor device according to some example embodiments.

Referring to FIG. 9, a semiconductor device 400 may be understood as having a structure similar to the semiconductor device 100 illustrated in FIGS. 1 to 6, except that the semiconductor device 400 further comprises a fourth interconnection pattern 125 that is substantially parallel to the second interconnection pattern 105 in the semiconductor device 300, a fourth conductive via 125V_1 in contact with the fourth interconnection pattern 125 and spaced apart from the first interconnection pattern 95, and a fifth conductive via 125V_2. Accordingly, the description of the semiconductor device 100 illustrated in FIGS. 1 to 6 may be combined with the description of the semiconductor device 400 according to this example embodiment, unless there is a description specifically to the contrary.

The semiconductor device 400 may further comprise the fourth interconnection pattern 125 extending substantially parallel to the second interconnection pattern 105, the fourth conductive via 125V_1 in contact with the fourth interconnection pattern 125 and spaced apart from the first interconnection pattern 95, and the fifth conductive via 125V_2.

The fourth interconnection pattern 125 may be comprised of a fourth conductive interconnection line 125W and a conductive via 125V. The fourth interconnection pattern 125 may extend substantially parallel to the second interconnection pattern 105 in the second horizontal direction (Y-direction). The first intermetallic insulating layer 98 may comprise a fourth via hole spaced apart from the first interconnection pattern 95 and a fifth via hole disposed on an opposite side of the fourth via hole with respect to the first interconnection pattern 95. The fourth conductive via 125V_1 may be disposed in the fourth via hole. The fifth conductive via 125V_2 may be disposed in the fifth via hole. The fourth conductive via 125V_1 may be spaced apart from the first interconnection pattern 95 and the first conductive via 105V_1. Upper surfaces of the fourth and fifth conductive vias 125V_1 and 125V_2 may be in contact with a lower surface of the fourth interconnection pattern 125. A height of the fourth and fifth conductive vias 125V_1 and 125V_2 in the vertical direction (Z-direction) may be substantially equal to a height of the first conductive via 105V_1 in the vertical direction (Z-direction).

When the fourth interconnection pattern 125 is added to the second interconnection structure WS2, the current flow in the OTP-ROM structure may be induced more smoothly. When the first interconnection pattern 95 disposed in the existing first interconnection structure WS1 is maintained unchangeably and the fourth interconnection pattern 125 is added at the same time, the fourth and fifth conductive vias 105V_4 and 105V_5 may be additionally comprised, so that the electrical connection with the first interconnection pattern 95 may be strengthened. This may further reduce a resistance value formed after the insulation breakdown, which may contribute to increasing the reliability of the semiconductor device 400. Additionally, when the fourth interconnection pattern 125 as well as the second interconnection pattern 105 is utilized, the current may be distributed, and local heat generation due to the current concentrated on the second interconnection pattern 105 may be reduced. During the programming process of the semiconductor device 400, damage due to overcurrent may be prevented, and more uniform insulation breakdown may be induced. By adding the fourth interconnection pattern 125, the current capacity of the interconnection lines comprised in the second interconnection structure WS2 may increase, and a fast and stable state transition may be performed due to the resistance reduction effect. The fourth interconnection pattern 125 may be added to serve to improve overall circuit performance. Accordingly, the OTP function of the semiconductor device 400 may operate more stably, and the durability and reliability of the semiconductor device 400 may be increased.

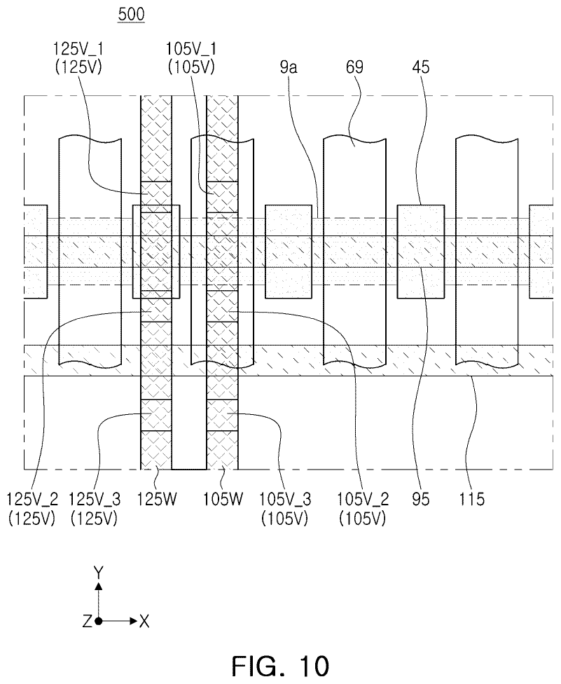

FIG. 10 is a schematic plan view of a semiconductor device according to some example embodiments.

Referring to FIG. 10, a semiconductor device 500 may be understood as having a structure similar to the semiconductor device 300 illustrated in FIG. 8, except that the semiconductor device 500 further comprises a third interconnection pattern 115 extending substantially parallel to the first interconnection pattern 95, a third conductive via 105V_3 disposed on an opposite side of the second conductive via 105V_2 with respect to the third interconnection pattern 115, a fourth interconnection pattern 125 extending substantially parallel to the second interconnection pattern 105, a fourth conductive via 125V_1 in contact with the fourth interconnection pattern 125 and spaced apart from the first interconnection pattern 95, a fifth conductive via 125V_2, and a sixth conductive via 125V_3. Accordingly, the description of the semiconductor device 100 illustrated in FIGS. 1 to 6 and the description of the semiconductor device 300 illustrated in FIG. 8 may be combined with the description of the semiconductor device 500 according to this example embodiment, unless there is a specifically contrary description.

The semiconductor device 500 may comprise a third interconnection pattern 115 extending substantially parallel to the first interconnection pattern 95, a third conductive via 105V_3 disposed on an opposite side of the second conductive via 105V_2 with respect to the third interconnection pattern 115, a fourth interconnection pattern 125 extending substantially parallel to the second interconnection pattern 105, a fourth conductive via 125V_1 in contact with the fourth interconnection pattern 125 and spaced apart from the first interconnection pattern 95, a fifth conductive via 125V_2, and a sixth conductive via 125V_3. The third interconnection pattern 115 may be comprised of a third conductive interconnection line 115W and a conductive via 115V. The fourth interconnection pattern 125 may be comprised of a fourth conductive interconnection line 125W and a conductive via 125V.

The first intermetallic insulating layer 98 may further comprise a fourth via hole spaced apart from the first interconnection pattern 95, a fifth via hole disposed opposite the fourth via hole with respect to the first interconnection pattern 95, and a sixth via hole disposed opposite the fifth via hole with respect to the third interconnection pattern 115.

The second interconnection structure WS2 may comprise a fourth conductive via 125V_1 filling the fourth via hole, a fifth conductive via 125V_2 filling the fifth via hole, a sixth conductive via 125V_3 filling the sixth via hole, and a fourth interconnection pattern 125 disposed on the first intermetallic insulating layer 98, the fourth, fifth and sixth conductive vias 125V_1, 125V_2 and 125V_3 and extending substantially parallel to the second interconnection pattern 105. The shapes of the fourth conductive via 125V_1, the fifth conductive via 125V_2, the sixth conductive via 125V_3 and the fourth interconnection pattern 125 may be substantially the same as the shapes of the first, second and third conductive vias 105V_1 and 105V_2 and 105V_3, and the second interconnection pattern 105, respectively. A height of the fourth, fifth and sixth conductive vias 125V_1, 125V_2 and 125V_3 may be substantially the same as the height of the first conductive via 105V_1.

When the interconnection patterns 115 and 125 are added to both the first interconnection structure WS1 and the second interconnection structure WS2, a current path of the fuse portion 98F may be further expanded, thereby further enhancing the OTP function. The addition of the third interconnection pattern 115 to the first interconnection structure WS1 may form a parallel structure with the existing first interconnection pattern 95, thereby increasing the current capacity, and further reducing the resistance after the insulation breakdown.

When the OTP-ROM structure is configured with three vias, the number of fuse parts 98F in which the insulation breakdown occurs may increase. The probability that the fuse part 98F is damaged may increase, and the OTP function may be performed more stably. In the multi-via structures 105V_1, 105V_2 and 105V_3 of the second interconnection pattern 105, even if the insulation breakdown occurs incompletely in a single conductive via, additional insulation breakdown may occur in other vias.

In the fourth interconnection pattern 125, in the multi-via structures 125V_1, 125V_2 and 125V_3, even if, for example, the insulation breakdown is incompletely performed in one conductive via, additional insulation breakdown may occur in other vias. This may increase a success rate in the programming process and may secure lower resistance. The reliability of the OTP-ROM structure may be improved and the current may flow more smoothly. Additionally, when the multi-via structure is utilized, the damage to the fuse portion 98F may occur simultaneously at multiple points rather than locally. This may allow the breakdown of the fuse portion 98F to be performed more uniformly, and the electrical characteristics to be maintained more stably. Such a design may contribute to improving the performance and lifespan of semiconductor devices.

Additionally, when the first interconnection pattern 95 disposed in the existing first interconnection structure WS1 is maintained unchangeably and the third interconnection pattern 115 is added at the same time, the second and third conductive vias 105V_2 and 105V_3 may be additionally comprised, so that an electrical connection with the third interconnection pattern 115 may occur. When the third interconnection pattern 115 as well as the first interconnection pattern 95 is utilized, the current may be distributed, and local heat generation due to the current concentrated on the first interconnection pattern 95 may be reduced. When the fourth interconnection pattern 125 is further added to the first interconnection pattern 95 and the third interconnection pattern 115 disposed in the first interconnection structure WS1, the fourth, fifth, and sixth conductive vias 125V_1, 125V_2 and 125V_3 may be additionally comprised, so that the electrical connection with the first and third interconnection patterns 95 and 115 may be strengthened. This may further reduce the resistance value formed after the insulation breakdown, which may contribute to increasing the reliability of the semiconductor device 500. Additionally, when the fourth interconnection pattern 125 as well as the second interconnection pattern 105 is utilized, the current may be distributed, and localized heat generation due to the current concentrated on the second interconnection pattern 105 may be reduced. This may prevent damage due to overcurrent during the programming process of the OTP-ROM semiconductor device 500 and may induce more uniform insulation breakdown.

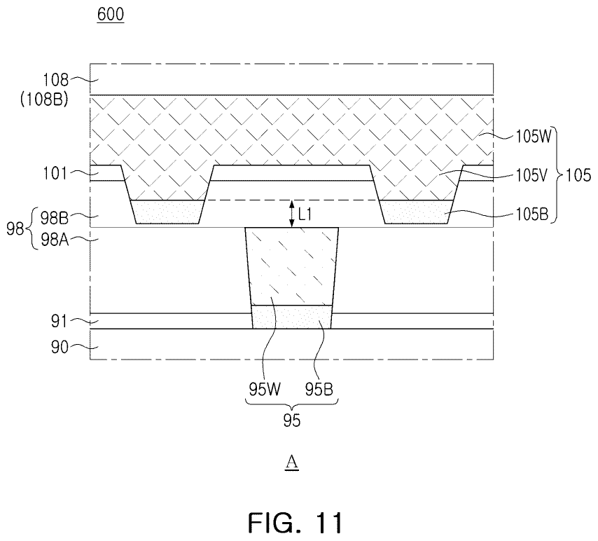

FIG. 11 is a partially enlarged cross-sectional view illustrating an exemplary example of a semiconductor device according to some example embodiments of the present disclosure.

Referring to FIG. 11, a semiconductor device 600 may be understood as having a structure similar to the semiconductor device 100 illustrated in FIGS. 1 to 6, except that a level of lower surfaces of the conductive vias 105V_1 and 105V_2 is higher than a level of the upper surface of the first interconnection pattern 95. Accordingly, the description of the semiconductor device 100 illustrated in FIGS. 1 to 6 may be combined with the description of the semiconductor device 600 according to this example embodiment, unless there is a specifically contrary description.

A level of the lower surfaces of the conductive vias 105V may be higher than a level of the upper surface of the first interconnection pattern 95. The level of the lower surface of the first conductive via 105V_1 may be higher than the level of the upper surface of the first interconnection pattern 95. The level of the lower surface of the second conductive via 105V_2 may be higher than the level of the upper surface of the first interconnection pattern 95. There may be a distance L1 in the vertical direction (Z-direction) between the lower surfaces of the conductive vias 105V and the upper surface of the first interconnection pattern 95.

Even if the conductive vias 105V_1 and 105V_2 and the first interconnection pattern 95 do not overlap one another in the second horizontal direction (Y-direction), the current path may be formed so that an operation of OTP-ROM may be performed. After programming, the electrical connection may still be maintained through the fuse portion 98F between the conductive vias 105V_1 and 105V_2 and the first interconnection pattern 95. When the insulation breakdown occurs, even if the conductive vias 105V_1 and 105V_2 and the first interconnection pattern 95 are spaced apart from one another in the vertical direction (Z-direction), the current may flow along the fuse portion 98F by utilizing an interconnection structure. Accordingly, even if the positions of the interconnection patterns do not completely overlap one another in the second horizontal direction (Y-direction), the function of the semiconductor device 600 may be performed normally. This design may secure flexibility in an interconnection layout.

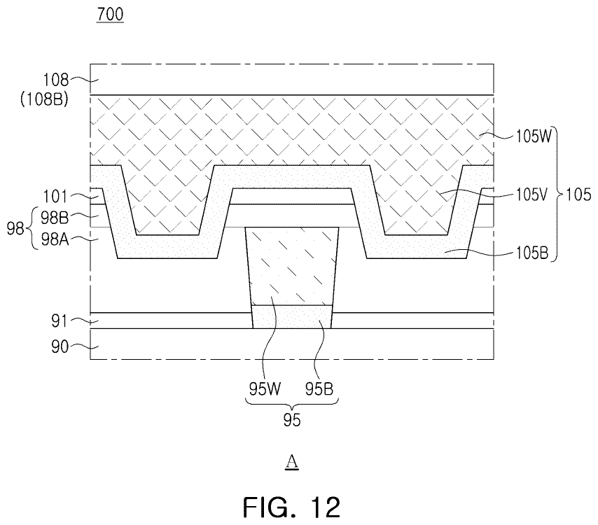

FIG. 12 is a partially enlarged cross-sectional view illustrating an exemplary example of a semiconductor device according to some example embodiments of the present disclosure.

Referring to FIG. 12, a semiconductor device 700 may be understood to have a structure similar to that of the semiconductor device 100 illustrated in FIGS. 1 to 6, except that the second interconnection pattern 105 comprises a second barrier layer 105B disposed along a lower surface of the second metal layer 105M and a lower surface and an internal surface of the conductive via 105V. Accordingly, the description of the semiconductor device 100 illustrated in FIGS. 1 to 6 may be combined with the description of the semiconductor device 700 according to this example embodiment, unless otherwise specifically stated.

The second barrier layer 105B may conformally extend on the first intermetallic insulating layer 98 and may be disposed between the first intermetallic insulating layer 98 and the second interconnection pattern 105. The second barrier layer 105B may be disposed to extend along the lower surface of the second interconnection pattern 105 and the internal surface and the lower surface of the conductive vias 105V. The second barrier layer 105B may be disposed between the second interconnection pattern 105 and the second etching stop layer 101. In a portion in which the second interconnection pattern 105 and the first interconnection pattern 95 intersect one another, the first interconnection pattern 95, the first intermetallic insulating layer 98, the second etching stop layer 101, the second barrier layer 105B and the second conductive interconnection line 105W may be disposed in this order.

When the barrier layer 105B is disposed to extend along a lower surface of the second conductive interconnection line 105W of the second interconnection pattern 105, the reliability and performance of the OTP-ROM semiconductor device 700 may be further improved. The barrier layer 105M may prevent diffusion of a metal into the first intermetallic insulating layer 98 of the second conductive interconnection line 105W of the second interconnection pattern 105 and may reduce the interface resistance between the metal and the first intermetallic insulating layer 98. Accordingly, the current flow may be stably maintained, and the resistance change formed after the insulation breakdown may be more precisely controlled. Through this design, the programming reliability of the OTP-ROM semiconductor device 700 may be increased and the long-term durability may be strengthened.

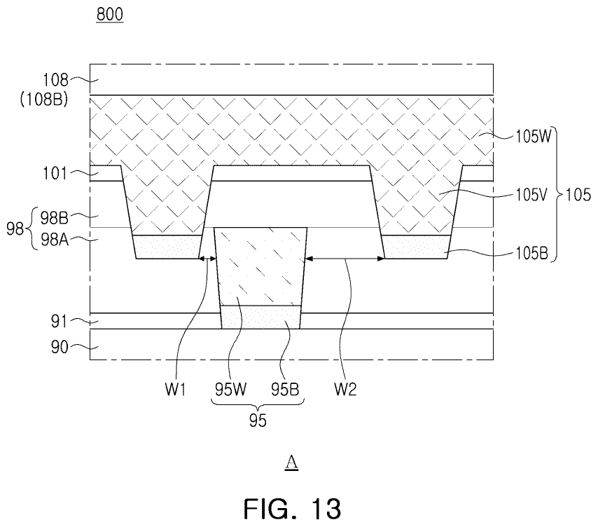

FIG. 13 is a partially enlarged cross-sectional view illustrating an exemplary example of a semiconductor device according to some example embodiments of the present disclosure.

Referring to FIG. 13, a semiconductor device 800 may be understood as having a structure similar to that of the semiconductor device 100 illustrated in FIGS. 1 to 6 except that distances w1 and w2 between each of the conductive vias 105V_1 and 105V_2 and the first interconnection pattern 95 are different from one another. Accordingly, the description of the semiconductor device 100 illustrated in FIGS. 1 to 6 may be combined with the description of the semiconductor device 800 according to this example embodiment, unless there is a particularly contrary description.

A distance W1 between the first conductive via 105V_1 and the first interconnection pattern 95 may be greater than or less than the distance W2 between the second conductive via 105V_2 and the first interconnection pattern 95. For example, the first interconnection pattern 95 may be misaligned toward one of the conductive vias 105V_1 and 105V_2, so that the first interconnection pattern 95 may be disposed close (W1) to the first conductive via 105V_1, among the conductive vias, and may be disposed far (W2) from the second conductive via 105V_2. For example, the first interconnection pattern 95 may be misaligned toward one of the conductive vias 105V_1 and 105V_2, so that the first interconnection pattern 95 may be disposed far (w1) from the first conductive via 105V_1, among the conductive vias, and may be disposed far (w2) from the second conductive via 105V_2 (not illustrated).

Even if the first interconnection pattern 95 is misaligned toward one of the conductive vias 105V_1 and 105V_2 and the first interconnection pattern 95 is disposed close (W1) to one of the conductive vias and is disposed far (W2) away from the other thereof, the OTP-ROM semiconductor device 800 may operate normally. This is because a current path does not depend on only one conductive via 150V_2, among the conductive vias 105V_1 and 105V_2, but may be supplemented by a structure in which multiple conductive vias 105V_1 and 105V_2 are disposed. The close first conductive via 105V_1 may provide a relatively low resistance path to induce a preferential current flow. The far second conductive via 105V_2 may also form an auxiliary conduction path after an insulation breakdown. After the fuse portion 98F is destroyed, an electrical connection may be formed, respectively, and the function of the semiconductor device 800 may be maintained regardless of the positions of the physical conductive vias 105V_1 and 105V_2. Through this structure, design flexibility may be secured while maintaining the reliability of the OTP-ROM semiconductor device 800 and the tolerance to process errors may be increased.

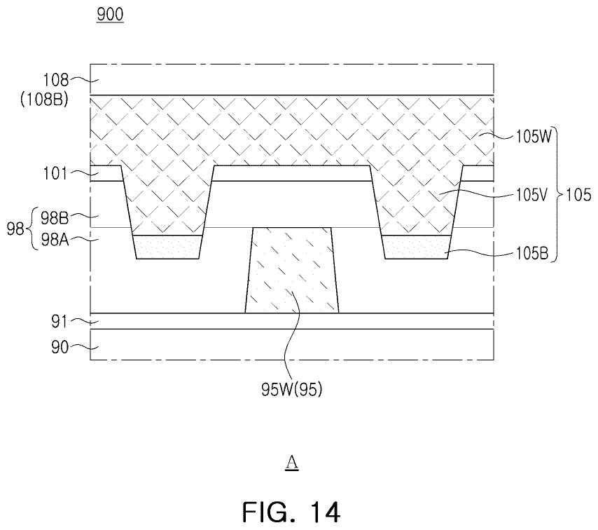

FIG. 14 is a vertical cross-sectional view taken along I-I′ illustrating an exemplary example of a semiconductor device according to some example embodiments of the present disclosure.

Referring to FIG. 14, a semiconductor device 900 may be understood as having a structure similar to that of the semiconductor device 900 illustrated in FIGS. 1 to 6 except that a width of the first interconnection pattern 95 decreases in a direction oriented toward the second interconnection pattern 105. Accordingly, the description of the semiconductor device 100 illustrated in FIGS. 1 to 6 may be combined with the description of the semiconductor device 900 according to this example embodiment, unless there is a particularly contrary description.

The first interconnection pattern 95 may have a shape in which a width thereof gradually decreases in the direction oriented toward the second intermetallic insulating layer 108 within the first intermetallic insulating layer 98. A width of the upper surface of the first interconnection pattern 95 may be smaller than a width of the lower surface of the first interconnection pattern 95.

The first interconnection pattern 95 may not comprise the first barrier layer 95B (see FIG. 3). The first interconnection pattern 95 may be comprised only of the first conductive interconnection line 95W. The first conductive interconnection line 95W may be comprised of the first metal layer 95M. The first metal layer 95M may be formed of ruthenium (Ru), molybdenum (Mo), or combinations thereof. The second interconnection pattern 105 may be formed of copper (Cu) or alloys thereof.

The conductive via 105V may have a shape in which a width thereof gradually increases in the direction oriented toward the second intermetallic insulating layer 108 within the first intermetallic insulating layer 98. A width of the upper surface of the conductive via 105V may be greater than a width of the lower surface of the conductive via 105V.

When forming the first interconnection pattern 95 of the semiconductor device 900, the first interconnection pattern 95 may be formed by directly patterning and disposing a metal, rather than first patterning the first intermetallic insulating layer 98 and then filling the first intermetallic insulating layer 98 with the metal. Accordingly, the number of operations required for a process of forming the first interconnection pattern 95 may be reduced. The first intermetallic insulating layer 98 formed in this manner may be formed at once without distinction between the lower first intermetallic insulating layer 98A and the upper first intermetallic insulating layer 98B.

When forming the first interconnection pattern 95, in a manner of first patterning the first intermetallic insulating layer 98 and then filling the first intermetallic insulating layer 98 with the metal, a process of etching the first intermetallic insulating layer 98, depositing the metal and then flattening the metal again may be required, but in a direct patterning method, such an additional process may be omitted. This may simplify the manufacturing process and may shorten the overall process time. The process error may also be reduced, so that the misalignment problem between the interconnection lines may be alleviated. This may contribute to reducing the manufacturing costs of semiconductor devices and improving productivity, and may increase the reliability of the semiconductor device 900.

When the first interconnection pattern 95 is formed by directly patterning and disposing the metal, this may be advantageous in improving the electrical characteristics of the first interconnection pattern 95. When the metal is directly patterned and formed, a first interconnection pattern 95 having a uniform structure may be formed. When forming the first metal layer 95M, the formation of voids may be avoided, and the interconnection resistance may be reduced and the reliability may be improved. When the formation of voids is avoided, electron mobility may be improved and the current may flow more smoothly. In this manner, a more stable programming operation may be ensured in the OTP-ROM semiconductor device 900.

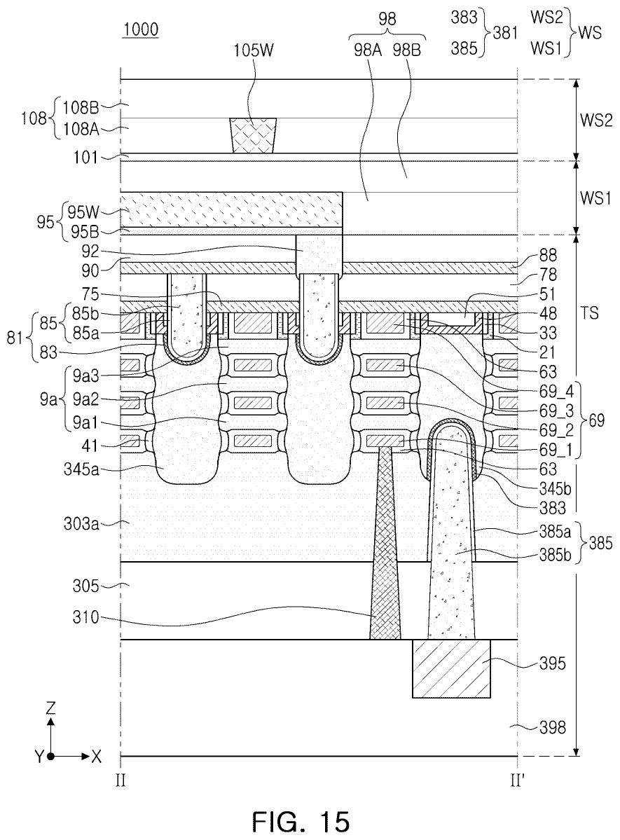

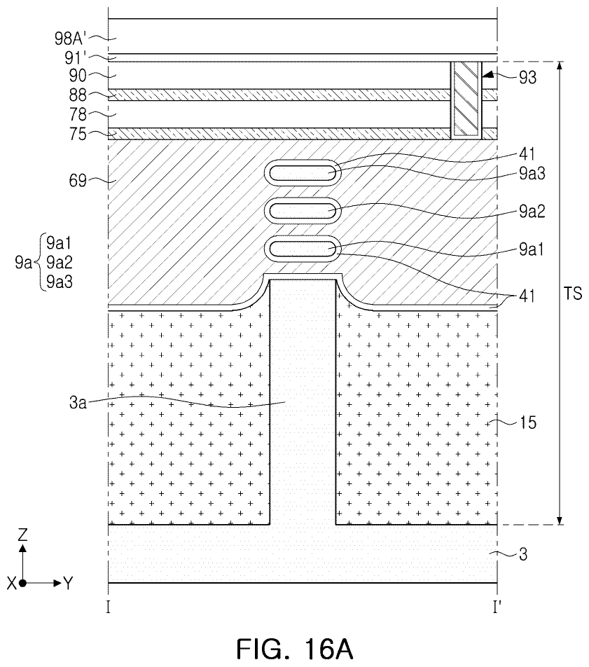

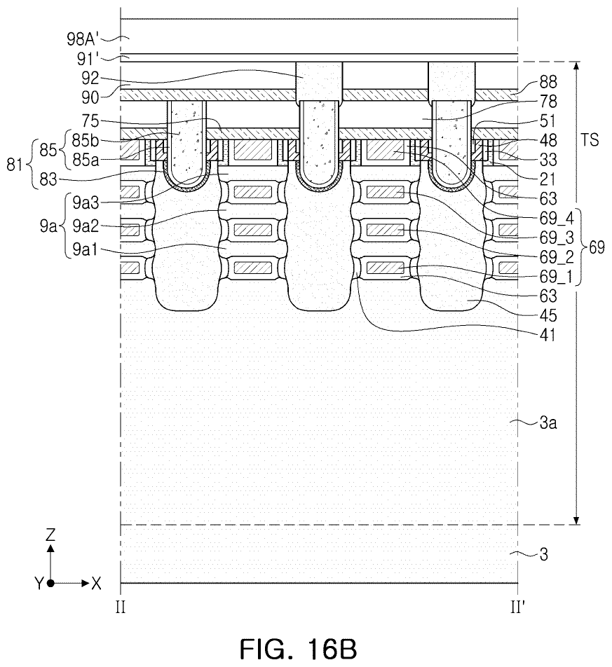

FIG. 15 is a vertical cross-sectional view taken along line II-II′ illustrating an exemplary example of a semiconductor device according to some example embodiments of the present disclosure. FIG. 15 is a cross-sectional view illustrating a region taken along line II-II′ of FIG. 1 to explain an exemplary example of a semiconductor device 1000 according to some example embodiments of the present disclosure, which may show a deformed portion in a cross-sectional section along line II-II′ of FIG. 4.

Referring to FIG. 15, the previously described source/drain regions 45 (see FIG. 4) may be replaced with a first-first source/drain region 345a and a first-second source/drain region 345b spaced apart from one another in the first horizontal direction (X-direction).

The substrate 3 and the first active region 3a previously described in FIGS. 2, 3 and 4 may be replaced with a semiconductor substrate 303a having a reduced thickness. The semiconductor substrate 303a may be disposed below the channel layer 9a, the gate electrodes 69, the first-first source/drain region 345a and the first-second source/drain region 345b.

The semiconductor device 1000 may further comprise a first rear insulating layer 305 below a semiconductor substrate 303a, rear interconnection structures 395 disposed below the first rear insulating layer 305, and a second rear insulating layer 398 covering the rear interconnection structures 395 below the first rear insulating layer 305.

The semiconductor device 1000 may further comprise insulating isolation structures 310 penetrating through the first rear insulating layer 305 and the semiconductor substrate 303a. The insulating isolation structures 310 may separate a portion of the semiconductor substrate 303a connected to the first-first source/drain region 345a and a portion of the semiconductor substrate 303a connected to the first-second source/drain region 345b.

At least one of the first source/drain contact structures 81 (see FIG. 4) connected to the source/drain regions 45 (see FIG. 4) described above may be replaced with rear contact structures 381 penetrating through the first rear insulating layer 305 and the semiconductor substrate 303a. For example, at least one of the first source/drain contact structures (81 in FIG. 4) connected to the source/drain regions (45 in FIG. 4) may be replaced with a rear source/drain contact structure connected to at least one corresponding source/drain region, among the first-first source/drain regions 345a and the first-second source/drain regions 345b. For example, one of the source/drain contact structures 81 (see FIG. 4) may be electrically connected to the first-first source/drain region 345a in the same form as in FIG. 4, and the other thereof may be replaced with a first rear source/drain contact structure 381 penetrating through the first rear insulating layer 305 and the semiconductor substrate 303a, passing through a lower surface of the first-second source/drain region 345b and extending into the first-second source/drain region 345b.

The rear source/drain contact structures 381 may comprise a metal-semiconductor compound layer 383 and a source/drain contact plug 385 below the metal-semiconductor compound layer 383. The source/drain contact plug 385 may comprise a plug conductive pattern 385b and a barrier layer 385a covering a side surface and an upper surface of the plug conductive pattern 385b. In each of the rear source/drain contact structures 381, the metal-semiconductor compound layer 383 may be in contact with the source/drain region 345b and a corresponding semiconductor substrate among the semiconductor substrate 303a. The rear source/drain contact structures 381 may be electrically connected to the rear interconnection structures 395.

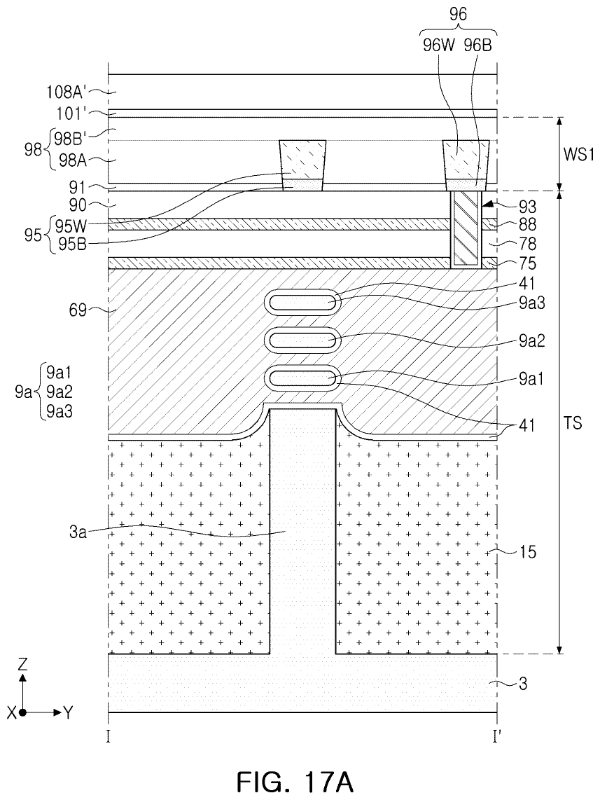

FIGS. 16A, 17A, 18A and 19A are cross-sectional views taken along line I-I′ illustrated according to a process sequence to explain a method of manufacturing a semiconductor device according to example embodiments. FIGS. 16B, 17B, 18B and 19B are cross-sectional views taken along line II-II′ illustrated according to the process sequence to explain a method of manufacturing a semiconductor device according to example embodiments.

Referring to FIGS. 16A and 16B, a preliminary first etch stop layer 91′ and a preliminary first intermetallic insulating layer 98′ may be formed on a transistor structure TS.

The preliminary first etch stop layer 91′ may be formed to cover upper surfaces of the second interlayer insulating layer 90 and the gate contact structure 93 of the transistor structure TS. The preliminary first etch stop layer 91′ may be formed by, for example, an atomic layer deposition (ALD) process. The preliminary first etch stop layer 91′ may conformally cover upper surfaces of the second interlayer insulating layer 90 and the gate contact structure 93.

Then, a lower surface of the preliminary lower first intermetallic insulating layer 98A′ may be formed to cover an upper surface of the preliminary first etching stop layer 91′. The preliminary lower first intermetallic insulating layer 98A′ may conformally cover the upper surface of the preliminary first etching stop layer 91′.

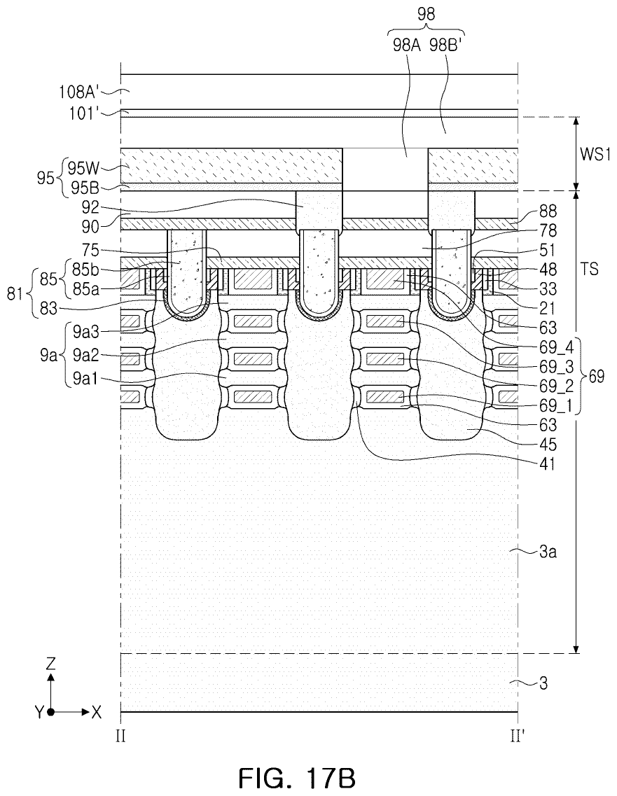

Referring to FIGS. 17A and 17B, a recess may be formed in the preliminary first intermetallic insulating layer 98′, and a first interconnection pattern 95 and a gate interconnection pattern 96 may be formed to fill the recess. A first metal insulating layer 98 may be additionally formed so that the first metal insulating layer 98 covers upper surfaces of the first interconnection pattern 95 and the gate interconnection pattern 96, and a second etching stop layer 101 and a second metal insulating layer 108 may be formed to cover an upper surface thereof.

A portion of the preliminary lower first intermetallic insulating layer 98A′ may be etched, and the upper surface of the preliminary first etching stop layer 91′ may be exposed. A photoresist may be applied onto the preliminary lower first intermetallic insulating layer 98A′ and the photoresist may be patterned by exposure and development to form a mask pattern. The preliminary lower first intermetallic insulating layer 98A′ may be etched using the mask pattern as an etching mask. An upper surface of the preliminary first etching stop layer 91′ may be exposed. An etching process of the preliminary first intermetallic insulating layer 98′ may be dry etching.

A recess may be formed in the preliminary lower first intermetallic insulating layer 98A′. The mask pattern may be removed using an ashing and stripping process, and an exposed portion of the preliminary first etching stop layer 91′ may be etched using the partially etched preliminary lower first intermetallic insulating layer 98A′ as an etching mask. An etching process may be performed until an upper surface of the gate contact 93 and a portion of the second interlayer insulating layer 90 are exposed. A recess may be formed in the preliminary lower first intermetallic insulating layer 98A′. The etching process of the exposed portion of the preliminary first etching stop layer 91′ may be wet etching. The exposed portion of the preliminary first etching stop layer 91′ may be etched to form the first etching stop layer 91.

Then, a first barrier layer 95B may be formed in the recess formed in the preliminary lower first intermetallic insulating layer 98A', and a first conductive interconnection line 95W filling an interior of the recess may be formed on the first barrier layer 95B. Specifically, the first barrier layer 95B may be formed substantially simultaneously to cover an upper surface of a portion of the first intermetallic insulating layer 98 exposed by the recess and an upper surface of the gate contact 93.

Then, a preliminary upper first intermetallic insulating layer 98B′ may be additionally formed to cover upper surfaces of the first interconnection pattern 95 and the gate interconnection pattern 96, and a preliminary second etch stop layer 101′ and a preliminary second intermetallic insulating layer 108′ may be formed to cover an upper surface thereof. A boundary between the preliminary upper first intermetallic insulating layer 98B′ and the preliminary lower first intermetallic insulating layer 98A′ may be difficult to identify with the naked eye.

A preliminary upper first intermetallic insulating layer 98B′ formed to cover upper surfaces of the first interconnection pattern 95 and the gate interconnection pattern 96 may be formed and a polishing process may be performed. The polishing process may be a chemical mechanical polishing (CMP) process.

Then, a preliminary second etching stop layer 101′ may be formed to conformally cover the upper surface of the first intermetallic insulating layer 98. The preliminary second etching stop layer 101′ may be formed, for example, by an atomic layer deposition process (ALD).

Then, a lower surface of the preliminary second intermetallic insulating layer 108′ may be formed to cover an upper surface of the preliminary second etching stop layer 101′. The preliminary second intermetallic insulating layer 108′ may conformally cover the upper surface of the preliminary second etching stop layer 101′.

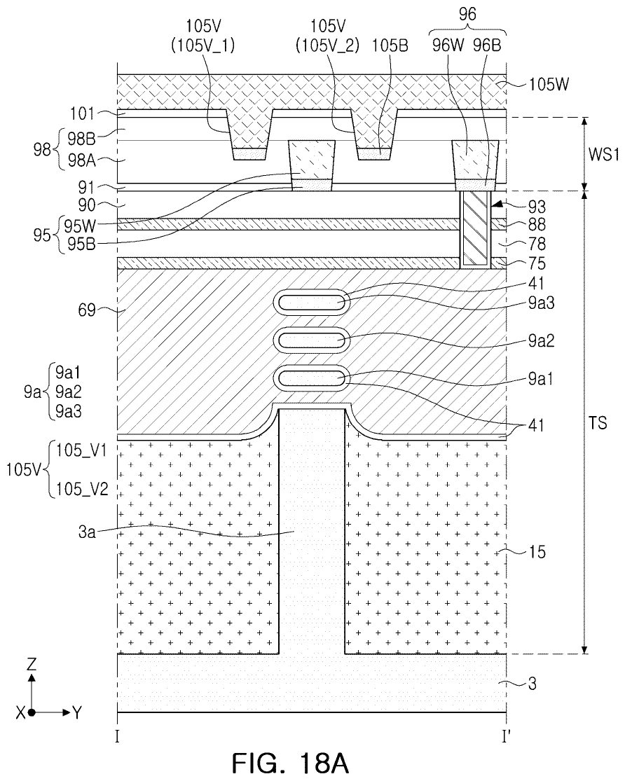

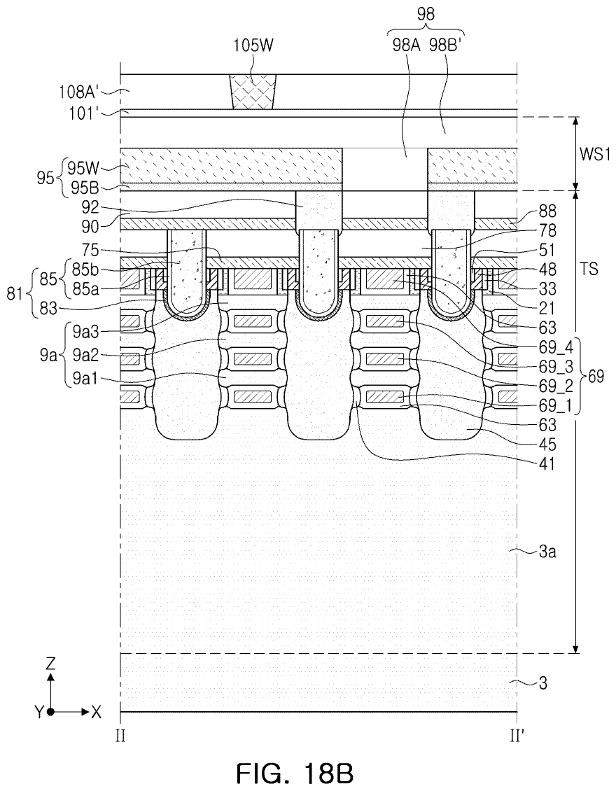

Referring to FIGS. 18A and 18B, a recess may be formed in the preliminary second intermetallic insulating layer 108′, and a second interconnection pattern 105 and conductive vias 105V filling the recess may be formed.

A preliminary lower second intermetallic insulating layer 108A′ may be etched to expose an upper surface of the preliminary second etch stop layer 101′. A photoresist may be applied onto the preliminary lower second intermetallic insulating layer 108A′ and the photoresist may be patterned by exposure and development to form a mask pattern. The preliminary lower second intermetallic insulating layer 108A′ may be etched using the mask pattern as an etching mask. The upper surface of the preliminary second etch stop layer 101′ may be exposed. An etching process of the preliminary lower second intermetallic insulating layer 108A′ may be dry etching.

A recess corresponding to the second conductive interconnection line 105W may be formed in the preliminary lower second intermetallic insulating layer 108A'. The mask pattern may be removed using an ashing and stripping process, and the partially etched preliminary lower second intermetallic insulating layer 108A′ may be used as an etching mask to etch an exposed portion of the preliminary second etch stop layer 101′. The etching process may be performed until a portion of the upper surface of the first intermetallic insulating layer 98 is exposed. A recess corresponding to the second conductive interconnection line 105W may be formed in the preliminary lower second intermetallic insulating layer 108A′. Subsequently, recesses corresponding to the conductive vias 105V may also be formed by penetrating through a portion of the preliminary upper first intermetallic insulating layer 98B′ and the preliminary lower first intermetallic insulating layer 98A′. The recess may comprise via holes for disposing the conductive vias 105V by etching a portion of an exposed portion of the preliminary second etch stop layer 101′. The etching process of the exposed portion of the preliminary second etch stop layer 101′ may be wet etching.

A second metal layer 105M may be formed. A second barrier layer 105B may be formed on a lower surface of the via holes for disposing the conductive vias 105V formed by penetrating through portions of the preliminary upper first intermetallic insulating layer 98B′ and the preliminary lower first intermetallic insulating layer 98A′, among the recesses formed in the preliminary lower second intermetallic insulating layer 108A′, and a second metal layer 105M filling an interior of the recesses corresponding to the via holes and the second conductive interconnection line 105W may be formed on the second barrier layer 105B. Specifically, the second barrier layer 105B may be formed to cover an upper surface of a portion of the first intermetallic insulating layer 98 exposed by the recess.

Then, referring further to FIGS. 1 to 4, a preliminary upper second intermetallic insulating layer 108B′ may be additionally formed to cover the upper surface of the second interconnection pattern 105, thereby forming the second intermetallic insulating layer 108. In this case, the preliminary upper second intermetallic insulating layer 108B′ and the preliminary lower second intermetallic insulating layer 108A′ may be difficult to identify with the naked eye.

The preliminary upper second intermetallic insulating layer 108B′ formed to cover the upper surface of the second interconnection pattern 105 may be formed and a polishing process may be performed. The polishing process may be a chemical mechanical polishing (CMP) process.

A method of manufacturing a semiconductor device according to some example embodiments of the present disclosure may comprise: forming a transistor structure; forming a first interconnection pattern on a first level, disposed on the transistor structure; forming a fuse insulating material covering the first interconnection pattern; forming a second interconnection pattern on a second level, higher than the first level on the fuse insulating material, and a fuse via respectively contacting a lower surface of the second interconnection pattern and disposed between the first level and the second level; and subjecting the fuse insulating material to an insulation breakdown when a voltage higher than a critical level is applied between the fuse via and the first interconnection pattern.

The subjecting the fuse insulating material to an insulation breakdown may comprise making the resistance of a fuse insulating material after the insulation breakdown smaller than that of a fuse insulating material before the insulation breakdown.

The subjecting the fuse insulating material to an insulation breakdown may comprise electrically connecting the first interconnection pattern, the fuse insulating material after the breakdown, the conductive via and the second interconnection patterns to one another.

Forming the first interconnection pattern may comprise forming the first interconnection pattern so as to extend on the transistor structure in a first direction, and Forming the second interconnection pattern may comprise forming the second interconnection pattern so as to extend in a second direction, intersecting the first direction.

Forming a fuse via disposed between the first level and the second level may comprise: forming the fuse via so as to overlap the first interconnection pattern in the second direction.

Forming a fuse via disposed between the first level and the second level may comprise forming the fuse via so as to be spaced apart from the first interconnection pattern in the second direction.

Forming the fuse via may comprise forming the fuse via so as to have a shape in which a width thereof gradually increases in a direction oriented toward the second interconnection pattern within the fuse insulating material.

Forming the fuse via may comprise forming the fuse via so that a distance from the first interconnection pattern is about 7 nm to about 10 nm.

Forming the first interconnection pattern may comprise forming the first interconnection pattern so that a width thereof gradually decreases in a direction oriented toward the second interconnection pattern within the fuse insulating material.

Forming the first interconnection pattern may comprise forming a first barrier layer disposed on the transistor structure within the fuse insulating material, and filling a metal material on the first barrier layer.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being comprised in the scope of the present disclosure.

What is claimed is:

1. A semiconductor device, comprising:
a first intermetallic insulating layer comprising a first interconnection pattern extending in a first direction, a conductive via disposed adjacently to the first interconnection pattern, and a fuse portion disposed between the first interconnection pattern and the conductive via; and
a second intermetallic insulating layer disposed on the first intermetallic insulating layer and comprising a second interconnection pattern contacting an upper surface of the conductive via and extending in a second direction, intersecting the first direction,
wherein the fuse portion is configured such that insulation breakdown occurs when a voltage higher than a critical level is applied between the conductive via and the first interconnection pattern.

2. The semiconductor device of claim 1, wherein after the voltage higher than the critical level is applied between the conductive via and the first interconnection pattern, the first interconnection pattern, the fuse portion, the conductive via and the second interconnection patterns are electrically connected to one another.

3. The semiconductor device of claim 1, wherein a level of a lower surface of the conductive via is higher than a level of an upper surface of the first interconnection pattern.

4. The semiconductor device of claim 1, wherein a level of a lower surface of the conductive via is equal to or lower than a level of an upper surface of the first interconnection pattern.

5. The semiconductor device of claim 1, wherein in the second direction, a distance between the conductive via and the first interconnection pattern is about 7 nm to about 10 nm, and
a thickness of the first interconnection pattern is about 15 nm to about 23 nm.

6. The semiconductor device of claim 1, wherein the first interconnection pattern, which is disposed within the first intermetallic insulating layer, has a shape in which a width thereof gradually decreases in a direction oriented toward the second intermetallic insulating layer, and
the conductive via, which is disposed within the first intermetallic insulating layer, has a shape in which a width thereof gradually increases in a direction oriented toward the second intermetallic insulating layer.

7. The semiconductor device of claim 1, further comprising:
a first barrier layer on a lower surface of the first interconnection pattern; and
a second barrier layer between a lower surface of the conductive via and an upper surface of the first intermetallic insulating layer.

8. The semiconductor device of claim 1, further comprising:
an etch stop layer conformally extending on the first intermetallic insulating layer and disposed between the first intermetallic insulating layer and the second interconnection pattern.

9. A semiconductor device, comprising:
a transistor structure;
a first interconnection structure on the transistor structure; and
a second interconnection structure on the first interconnection structure,
wherein the first interconnection structure comprises:
a first interconnection pattern extending in a first direction; and
a first intermetallic insulating layer covering an upper surface of a portion of the transistor structure, an upper surface and side surfaces of the first interconnection pattern, and having a first via hole spaced apart from the first interconnection pattern,
wherein the second interconnection structure comprises:
a first conductive via filling the first via hole of the first intermetallic insulating layer;
a second interconnection pattern disposed on the first intermetallic insulating layer and the first conductive via, extending in a second direction, intersecting the first interconnection pattern, and contacting an upper surface of the first conductive via; and
a second intermetallic insulating layer covering an upper surface of a portion of the first interconnection structure, and side surfaces of the second interconnection pattern,
wherein a thickness of the first intermetallic insulating layer is greater than a height of the conductive via.

10. The semiconductor device of claim 9, wherein the first intermetallic insulating layer further comprises a second via hole on an opposite side of the first via hole with respect to the first interconnection pattern,
the second interconnection structure further comprises a second conductive via filling the second via hole,
an upper surface of the second conductive via is in contact with a lower surface of the second interconnection pattern, and
a height of the second conductive via is substantially the same as a height of the first conductive via.

11. The semiconductor device of claim 10, wherein a distance between the first conductive via and the first interconnection pattern is substantially the same as a distance between the second conductive via and the first interconnection pattern.

12. The semiconductor device of claim 10, wherein a distance between the first conductive via and the first interconnection pattern is smaller than a distance between the second conductive via and the first interconnection pattern.

13. The semiconductor device of claim 10, wherein the first interconnection structure further comprises a third interconnection pattern extending substantially parallel to the first interconnection pattern,
the first intermetallic insulating layer further comprises a third via hole on an opposite side of the second via hole with respect to the third interconnection pattern,
the second interconnection structure further comprises a third conductive via filling the third via hole,
wherein the second conductive via is disposed between the first interconnection pattern and the third interconnection pattern, and
wherein an upper surface of the third conductive via is in contact with the second interconnection pattern.

14. The semiconductor device of claim 10, wherein the first intermetallic insulating layer further comprises a fourth via hole spaced apart from the first interconnection pattern and a fifth via hole disposed on an opposite side of the fourth via hole with respect to the first interconnection pattern,
the second interconnection structure further comprises a fourth conductive via filling the fourth via hole, a fifth conductive via filling the fifth via hole, a fourth interconnection pattern disposed on the first intermetallic insulating layer and the fourth conductive via and the fifth conductive via and extending substantially parallel to the second interconnection pattern, and
heights of the fourth conductive via and the fifth conductive via are substantially the same as a height of the first conductive via.

15. The semiconductor device of claim 13, wherein the first intermetallic insulating layer further comprises a fourth via hole spaced apart from the first interconnection pattern, a fifth via hole disposed on an opposite side of the fourth via hole with respect to the first interconnection pattern, and a sixth via hole disposed on an opposite side of the fifth via hole with respect to the third interconnection pattern,
the second interconnection structure further comprises a fourth conductive via filling the fourth via hole, a fifth conductive via filling the fifth via hole, a sixth conductive via filling the sixth via hole, and a fourth interconnection pattern disposed on the first intermetallic insulating layer and the fourth conductive via, the fifth conductive via and the sixth conductive via, and extending substantially parallel to the second interconnection pattern, and
heights of the fourth conductive via, the fifth conductive via, and the sixth conductive via are substantially the same as a height of the first conductive via.

16. The semiconductor device of claim 9, wherein the transistor structure comprises:
a substrate;
an active region extending in the first direction on the substrate;
a plurality of channel layers spaced apart from one another in a third direction, perpendicular to the first and second directions and disposed on the active region;
a gate structure extending in the second direction by intersecting the active region and the plurality of channel layers on the substrate, and surrounding each of the plurality of channel layers;
a source/drain region disposed on one side surface of the gate structure and connected to the plurality of channel layers; and
a source/drain contact structure connected to the source/drain region and disposed on the source/drain region,
wherein an upper surface of the source/drain contact structure is in contact with a portion of a lower surface of the first interconnection pattern.

17. A semiconductor device, comprising:
a first interconnection pattern on a first level;
a second interconnection pattern on a second level, higher than the first level;
conductive vias respectively contacting a lower surface of the second interconnection pattern and disposed between the first level and the second level;
a fuse via, which is one of the conductive vias and is adjacent to the first interconnection pattern;
a fuse insulating material between the fuse via and the first interconnection pattern,
wherein the fuse insulating material is configured such that insulation breakdown occurs when a voltage higher than a critical level is applied between the fuse via and the first interconnection pattern.

18. The semiconductor device of claim 17, wherein the first interconnection pattern, the fuse insulating material after the insulation breakdown, the conductive via, and the second interconnection patterns are electrically connected to one another.

19. The semiconductor device of claim 17, wherein the second interconnection pattern extends in a first direction, and
the fuse via overlaps the first interconnection pattern in the first direction.

20. The semiconductor device of claim 17, wherein the first interconnection pattern comprises ruthenium (Ru) or alloys thereof,
the second interconnection pattern comprises copper (Cu) or alloys thereof, and
the fuse insulating material comprises an oxide.
